(19) United States
(12) Patent Application Publication
(10) Pub. No.: US 2026/0362940 A1
(43) Pub. Date: Nov. 12, 2026

(54) THIN ANODE HIGH RESOLUTION ADVANCED OLED SUB-PIXEL CIRCUIT AND PATTERNING

(71) Applicants: Applied Materials, Inc., Santa Clara, CA (US); MICROOLED, S.A., Grenoble (FR)

(72) Inventors: Gunther HAAS, Saint Egrève (FR); Jungmin LEE, Santa Clara, CA (US); Eric LANGER, Grenoble (FR); Sylvain DE VECCHI, Chambéry (FR)

(21) Appl. No.: 19/665,762

(22) Filed: May 1, 2026

Related U.S. Application Data
(60) Provisional application No. 63/800,981, filed on May 6, 2025.

(51) Int. Cl. H10K 59/80

(52) U.S. Cl. CPC H10K 59/80515; H10K 59/80522

(57) ABSTRACT

Embodiments described herein relate to sub-pixel circuits. The sub-pixel circuits include at least two isolation structures disposed over a substrate, adjacent isolation structures defining a well, anodes disposed over an upper surface of the isolation structures, separation structures, an organic light emitting diode (OLED) material, a cathode disposed over the OLED material, an assistant cathode disposed over the cathode, and an encapsulation layer disposed over the assistant cathode. The anode includes a tapered surface. The separation structures include a tapered portion disposed over the tapered surface of the anodes and a bottom surface extending past a sidewall of at least two isolation structures to form a separation extension.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices, including display devices, may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through a lid that is added following the fabrication of the device. OLEDs are used to create display devices in many electronics today. Today's electronics manufacturers are pushing these display devices to shrink in size while providing higher resolution, i.e., increase pixel-per-inch, than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance.

Accordingly, what is needed in the art are sub-pixel circuits and methods of forming sub-pixel circuits to increase pixel-per-inch and provide improved OLED performance.

### SUMMARY

Embodiments described herein generally relate to display devices. More specifically, embodiments described herein relate to sub-pixel circuits and methods of forming sub-pixel circuits that may be utilized in display devices, such as an organic light-emitting diode (OLED) displays.

In one embodiment, a sub-pixel circuit includes at least two isolation structures disposed over a substrate, anodes disposed over an upper surface of the isolation structures, separation structures partially disposed over the anodes, an organic light emitting diode (OLED) material disposed over the anodes and separation structures, a cathode disposed over the OLED material, and an encapsulation layer disposed thereover. Adjacent isolation structures define a well therebetween. The anode includes a tapered surface proximate to the well. The separation structures include a tapered portion disposed over the tapered surface of the anode and a bottom surface. The tapered portion is disposed over the tapered surface of the anodes and extending into the well. The bottom surface extends past a sidewall of the at least two isolation structures to form a separation extension.

In another embodiment, a device includes a first sub-pixel and a second sub-pixel, each sub-pixel includes isolation structures disposed over a substrate, anodes disposed over the isolation structures, a plurality of separation structures, an organic light emitting diode (OLED) material, a cathode disposed over the OLED material, and an assistant cathode disposed over the cathode. The isolation structures include an isolation material. The separation structures are disposed over the anodes and include an upper portion extending over a portion of an uppermost surface of the anodes, a lower portion extending past a sidewall of the isolation structures to form a separation extension, and an intermediate portion spanning between the upper portion and the lower portion.

In yet another embodiment, at least two isolation structures are disposed over a substrate, adjacent isolation structures defining a well, anodes disposed over an upper surface of the isolation structures, separation structures partially disposed over the anodes, an organic light emitting diode (OLED) material disposed over the anodes and the separation structures, a cathode disposed over the OLED material, an assistant cathode disposed over the cathode, and an encapsulation layer disposed over the assistant cathode. The anode includes a tapered surface that enables the OLED material and the cathode to remain continuous in the y-direction, forming a common cathode that can be connected by horizontal bus bars outside of the active area. The separation structures including a tapered portion disposed over the tapered surface of the anodes and a bottom surface extending past a sidewall of the at least two isolation structures to form a separation extension.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, top view of a sub-pixel circuit having a line-type architecture, according to embodiments.t/00

FIG. 1B is a schematic, cross-sectional view of a first sub-pixel circuit at section line 1B-1B, according to embodiments.

FIG. 1C is a schematic, cross-sectional view of a first sub-pixel circuit of FIG. 1A at section line 1C-1C, according to embodiments.

FIG. 2 is a schematic, cross-sectional view of a separation structure, according to embodiments.

FIG. 3 is a flow diagram of a method for forming a sub-pixel, according to embodiments.

FIGS. 4A-4O are schematic, cross-sectional views of a substrate during a method of forming a sub-pixel, according to embodiments.

FIG. 5A is a schematic, cross-sectional view of a sub-pixel circuit at section line 1A-1A according to embodiments.

FIG. 5B is a schematic, cross-sectional view of a sub-pixel circuit at section line 1B-1B, according to embodiments.

FIG. 6 is a schematic, cross-sectional view of a separation structure, according to embodiments.

FIG. 7 is a flow diagram of a method for forming a sub-pixel, according to embodiments.

FIGS. 8A-8O are schematic, cross-sectional views of a substrate during a method of forming a sub-pixel, according to embodiments.

FIG. 9A is a schematic, cross-sectional view of a third sub-pixel circuit at section line 1A-1A, according to embodiments.

FIG. 9B is a schematic, cross-sectional view of a third sub-pixel circuit at section line 1B-1B, according to embodiments.

FIG. 10 is a schematic, cross-sectional view of a third sub-pixel circuit, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to display devices. More specifically, embodiments described herein relate to sub-pixel circuits and methods of forming sub-pixel circuits that may be utilized in a display devices such as an organic light-emitting diode (OLED) display devices. In various embodiments, the sub-pixel circuits employ advanced separation structures to improve functionality of the display devices.

A sub-pixel circuit includes a substrate and isolation structures formed on or over the substrate. The substrate provides structural support for the sub-pixel circuit. In some embodiments, a protective layer may be disposed over the substrate. The isolation structures are formed on or over the protective layer. The isolation structures extend along a y-direction and at least partially define a well. The sub-pixel circuit has a plurality of sub-pixel lines. The sub-pixel lines are adjacent to each other along a x-direction. Each sub-pixel line includes at least two sub-pixels. Adjacent sub-pixel lines are divided by an opening of a well that extends along the y-direction in-between the isolation structures of adjacent sub-pixel lines. Each sub-pixel line includes two separation structures extending along the y-direction, disposed on an outer edge of the isolation structures. The separation structures are disposed on or over the outer edge of the isolation structure and extend over at least a portion of the well. Each sub-pixel line includes an OLED material and a cathode disposed over the anode and the separation structures. The sub-pixel circuit includes an encapsulation layer. The encapsulation layer may be or may correspond to a local passivation layer. The encapsulation layer of a respective sub-pixel is disposed over the cathode (and OLED material) within an area of the well, with the encapsulation layer extending under at least a portion of each of the separation extensions and along a sidewall of each of the adjacent isolation structures. In one or more embodiments, a global encapsulation layer is disposed over the encapsulation layer. The global encapsulation layer fills the area and the opening and covers the entirety of the sub-pixel circuit. Each sub-pixel line includes one or more separation structures, with adjacent sub-pixels sharing a separation structure in the y-direction. The OLED material is disposed over and in contact with the uppermost surface of the anode and the separation structure in the y-direction. The cathode is disposed over the OLED material in the y-direction.

In some embodiments, different compositions of the isolation structures and the separation structures result in different etch rates such that the separation structures have extensions that extend past a lower sidewall of the isolation structure as described herein.

Each of the embodiments of the sub-pixel circuits described herein include a plurality of sub-pixels with each of the sub-pixels defined by adjacent separation structures. While the Figures depict two sub-pixels or three sub-pixels with each sub-pixel defined by adjacent separation structures, the sub-pixel circuit of embodiments described herein generally include a plurality of sub-pixels, such as two or more subpixels. Each sub-pixel has OLED materials configured to emit a white, red, green, blue or other color light when energized. For example, the OLED materials of a first sub-pixel emit a red light when energized, the OLED materials of a second sub-pixel emit a green light when energized, and the OLED materials of a third sub-pixel emit a blue light when energized.

The sub-pixel circuit is formed using evaporation deposition. The separation structures are permanent to the sub-pixel circuit, e.g., the separation structures remain in place after the sub-pixel circuit is formed. The separation structures defining each sub-pixel of the sub-pixel circuit of the display provide for formation of the sub-pixel circuit by providing a shadowing effect during evaporation deposition. Evaporation deposition is utilized for deposition of OLED materials (including a hole injection layer (HIL), a hole transport layer (HTL), an emissive layer (EML), and an electron transport layer (ETL)) and cathode. In some instances, an encapsulation layer may be deposited via evaporation deposition. The separation structures and the evaporation angle set by the evaporation source define the deposition angles, i.e., the separation structures provide for a shadowing effect during evaporation deposition with the evaporation angle set by the evaporation source. In order to deposit at a particular angle, the evaporation source is configured to emit the deposition material at a particular angle with regard to the separation structure. The encapsulation layer of a respective subpixel is disposed over the cathode. The encapsulation layer extends under at least a portion of each of the adjacent separation structures and along a sidewall of each of the adjacent isolation structures.

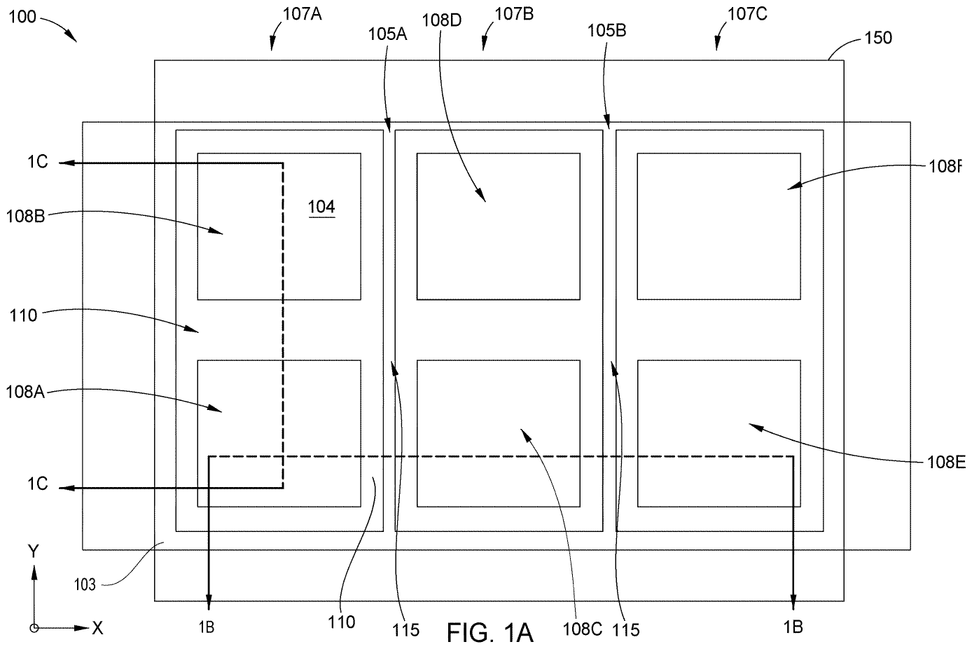

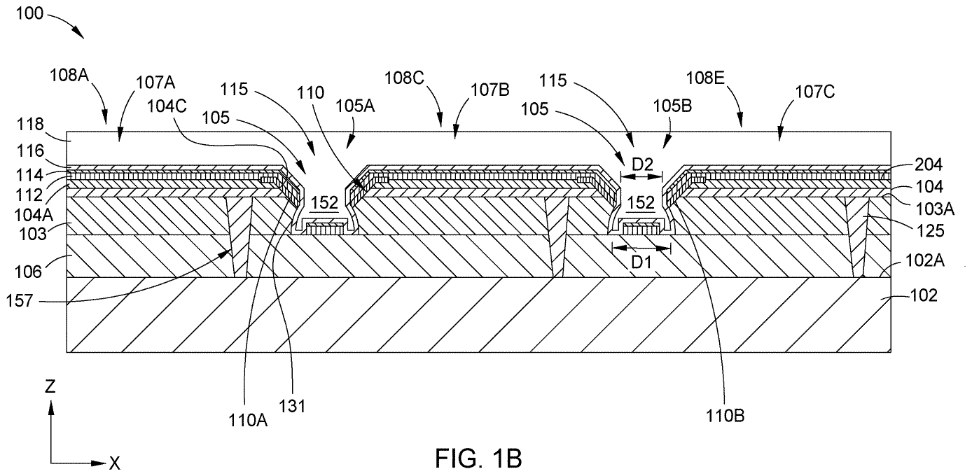

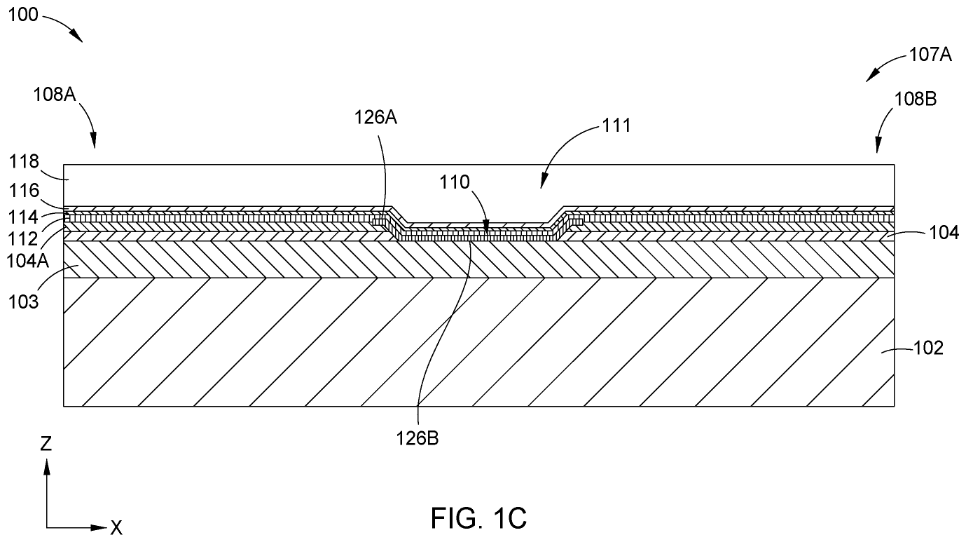

FIG. 1A is a schematic, top view of a sub-pixel circuit 100. It should be understood that FIG. 1A is not shown with the protective layer 106, OLED material 112, the cathode 114, the encapsulation layer 116, or the global encapsulation layer 118, for illustrative purposes. FIG. 1B is a schematic, cross-sectional view of a sub-pixel circuit 100, according to one embodiment. The cross-sectional view of FIG. 1B is taken along section line 1B-1B of FIG. 1A (e.g., a pixel plane or x-direction). FIG. 1C is a schematic, cross-sectional view of a sub-pixel circuit 100. The cross-sectional view of FIG. 1C is taken along section line 1C-1C of FIG. 1A (e.g., a line plane or y-direction). The sub-pixel circuit 100 includes a substrate 102. In one or more embodiments, the substrate 102 is a backplane. The backplane includes, but is not limited to, a complementary metal-oxide-semiconductor (CMOS) array, a thin-film transistor (TFT) array, or a glass backplane. In some embodiments, the substrate 102 includes a dielectric material such as a silicon oxide, a silicon nitride, a silicon oxynitride, or a combination thereof.

A protective layer 106 is disposed over the substrate 102. The protective layer 106 may be formed along both the x-direction and the y-direction. The protective layer 106 may be disposed on an upper surface 102A of the substrate 102. The protective layer 106 is formed of a protective material. In one or more embodiments, the protective material includes aluminum oxide (Al₂O₃), silicon nitride (SiNₓ), silicon oxide (SiO₂), or a combination thereof. In one or more embodiments, the protective layer 106 has a thickness of about 10 nm to about 700 nm, such as a thickness of about 400 nm. In one or more embodiments, the protective layer 106 has a thickness from about 300 nm to about 500 nm.

Isolation structures 103 are formed on or over the substrate 102. In one or more embodiments, the isolation structures 103 are formed on or over the protective layer 106. The isolation structures 103 extend along the y-direction. Adjacent isolation structures 103 at least partially define a well 105. Each isolation structure 103 includes an isolation material. In one or more embodiments, the isolation material includes aluminum oxide (Al₂O₃), silicon nitride (SiNₓ), silicon oxide (SiO₂), or a combination thereof. The isolation material and the protective material are different from one another. The isolation structures 103 have a thickness of about 0.3 μm to about 1 μm, such as a thickness of about 0.4 μm to about 0.5 μm. In one or more embodiments, an opening 157 extends from an upper surface 103A of the isolation structure 103 to an upper surface 102A of the substrate 102. The isolation structures 103 at least partially define a well 105 having an area 152 of the sub-pixel circuit 100.

Anodes 104 are disposed on or over the isolation structures 103. In one or more embodiments, the anodes 104 include a combination of aluminum and a top layer of a transparent conductive oxide (TCO), such as indium tin oxide (ITO), indium zinc oxide (IZO), tin oxide (SnO₂), zinc oxide (ZnO), aluminum doped zinc oxide (AZO), or a combination thereof. In one or more embodiments, the anodes 104 include a combination of an aluminum layer having a thickness of about 50 nm to about 500 nm, such as about 100 nm, to about 200 nm, and a layer of titanium nitride (TiN) having a thickness of about 4 nm to about 12 nm. In one or more embodiments, the anodes 104 include a transparent, conductive oxide (TCO) multilayer anode 104A made of three layers. The three layers of the TCO multilayer anode 104A include a first layer of indium tin oxide (ITO), a second layer of silver (Ag), and a third layer of ITO. The anodes may further comprise a tapered portion 104C. The tapered portion 104C extends into the area 152 of the well 105. In one or more embodiments, the anode 104 has a thickness of about 10 nm to 50 nm, such as 20 nm. In one or more embodiments, the anode has a thickness of about 50 nm to about 500 nm, such as about 100 nm to about 200 nm. The anodes 104 are configured to operate as anodes of respective sub-pixels.

In one or more embodiments, a connecting portion 125 of each anode 104 extends through the opening 157 and contacts the substrate 102. In one or more embodiments, the connecting portion 125 of the anode 104 covers the outer surface of the opening 157. In one or more embodiments, a filling material is deposited within the opening 157 in order to fill the opening 157. In one or more embodiments, the filling material includes copper. The connecting portion 125 of the anode 104 contacts one or more circuits formed on the substrate 102. In one or more embodiments, the connecting portion 125 of the anode 104 is a plug-in via metal. The plug in via metal includes a metal material, such as tungsten or copper.

The sub-pixel circuit 100 has a plurality of sub-pixel lines (e.g., first sub-pixel line 107A, second sub-pixel line 107B, and third sub-pixel line 107C). The sub-pixel lines are adjacent to each other along the pixel plane. Each sub-pixel line includes at least two sub-pixels. E.g., the first sub-pixel line 107A includes a first sub-pixel 108A and a second sub-pixel 108B, the second sub-pixel line 107B includes a third sub-pixel 108C and a fourth sub-pixel 108D, and the third sub-pixel line 107C includes a fifth sub-pixel 108E and a sixth sub-pixel 108F. The first sub-pixel 108A and the second sub-pixel 108B are aligned along the y-direction. The first sub-pixel 108A, the third sub-pixel 108C, and the fifth sub-pixel 108E are aligned in the x-direction. While FIG. 1A depicts the first sub-pixel line 107A, the second sub-pixel line 107B, and the third sub-pixel line 107C, the sub-pixel circuit 100 of the embodiments described herein may additional sub-pixel lines such as a fourth sub-pixel line. Each sub-pixel line has OLED materials configured to emit a white, red, green, blue or other color light when energized. E.g., the OLED materials of the first sub-pixel line 107A emits a red light when energized, the OLED materials of the second sub-pixel line 107B emits a green light when energized, the OLED materials of the third sub-pixel line 107C emits a blue light when energized, and the OLED materials of a fourth sub-pixel emits another color light when energized. The OLED materials within a sub-pixel line may be configured to emit the same color light when energized. E.g., the OLED materials of the first sub-pixel 108A and the second sub-pixel 108B of the first sub-pixel line 107A emit a red light when energized and the OLED materials of the third sub-pixel 108C and the fourth sub-pixel 108D of the second sub-pixel line 107B emit a green light when energized.

Adjacent sub-pixel lines are divided by an opening 115 of the well 105 that extends along the y-direction in-between the isolation structures 103 of adjacent sub-pixel lines. For example, FIG. 1A illustrates sub-pixel circuit 100 including a first well 105A and a second well 105B. The first well 105A is defined by the isolation structure 103 of the first sub-pixel 108A and the second sub-pixel 108B of first sub-pixel line 107A, and the isolation structure 103 of the third sub-pixel 108C and the fourth sub-pixel 108D of the second sub-pixel line 107B. The opening 115 of the first well 105A divides the first sub-pixel line 107A and the second sub-pixel line 107B. The second well 105B is defined by the isolation structure 103 of the third sub-pixel 108C and the fourth sub-pixel 108D of second sub-pixel line 107B, and the isolation structure 103 of the fifth sub-pixel 108E and the sixth sub-pixel 108F of the third sub-pixel line 107C. The opening 115 of the second well 105B divides the second sub-pixel line 107B and the third sub-pixel line 107C.

Each sub-pixel line includes two separation structures 110 extending along the y-direction, disposed on an outer edge of the isolation structures 103. The separation structures are disposed on or over the outer edge of the isolation structure 103 and extends over at least a portion of the well 105. For example, the second sub-pixel line 107B includes a first separation structure 110A and a second separation structure 110B disposed on adjacent isolation structures 103 of the third sub-pixel 108C and the fourth sub-pixel 108D. The separation structure 110 includes a separation material. The separation material includes silicon (Si), silicon nitride (Si₃N₄), silicon oxide (SiO₂), aluminum oxide (Al₂O₃), or combinations thereof. The isolation material and the separation material are different in composition from one another. The separation material and the isolation material have different etch rates when exposed to the same etch chemistries, due at least to the differing compositions. In some embodiments, the protective material and the separation material are the same. The sidewalls 131 of the adjacent isolation structures 103 are separated by a distance D1. The opening 115 has a distance D2. The separation structures 110 have a thickness of about 10 nm to about 100 nm, such as about 25 nm to about 75 nm, such as about 40 nm to about 60 nm. In some embodiments, the relationship between D1 and D2 is such that

$$\frac{( D 1 - D 2 )}{2}$$

is about 50 nm to about 200 nm.

Each sub-pixel line includes an OLED material 112 and a cathode 114 disposed over the anode 104 and the separation structures 110. The OLED material 112 may include one or more of a HIL, a HTL, an EML, and an ETL. The OLED material 112 is disposed over and in contact with the uppermost surface 204 of the anodes 104 within a sub-pixel line. The OLED material 112 is disposed within at least a portion the area 152 not shadowed by the separation extensions 109. The OLED material 112 may also be disposed within a portion of the area 152 shadowed by the separation extensions 109.

The cathode 114 is disposed over the OLED material 112. The cathode 114 includes a conductive material, such as a metal. E.g., the cathode 114 includes, but is not limited to, silver, magnesium, chromium, titanium, aluminum, ITO, or a combination thereof. The material of the cathode 114 is different from the separation material.

The sub-pixel circuit 100 includes an encapsulation layer 116. The encapsulation layer 116 may be or may correspond to a local passivation layer. The encapsulation layer 116 of a respective sub-pixel is disposed over the cathode 114 (and OLED material 112) within the area 152, with the encapsulation layer 116 extending under at least a portion of each of the separation extensions 109 and along the sidewall 131 of each of the adjacent isolation structures 103. The encapsulation layer 116 is disposed over the cathode 114 and over at least the sidewall 131. The encapsulation layer 116 includes the non-conductive inorganic material, such as aluminum oxide (Al₂O₃), a silicon-containing material, such as SiO₂ or Si₃N₄, or a conductive inorganic material, such as a transparent conductive oxide, such as ITO, ZnO, AZO, or SnO₂, deposited by a conformal deposition method such as atomic layer deposition (ALD) or chemical vapor deposition (CVD). When the encapsulation layer is a conductive inorganic material, it may function to electrically connect the cathodes 114 to form an assistant cathode.

In one or more embodiments, a global encapsulation layer 118 is over the encapsulation layer 116. The global encapsulation layer 118 layer fills the area 152 and the opening 115 and covers the entirety of the sub-pixel circuit 100.

Each sub-pixel line includes one or more separation structures 110, with sub-pixels of adjacent sup-pixel lines sharing a separation structure 110 aligned along the y-direction. The separation structures 110 are permanent to the sub-pixel circuit 100. The separation structures 110 further define each sub-pixel of the sub-pixel line. The separation structures 110 form a trench in the isolation structures 103 in-between the anodes 104 of the sub-pixels within a sub-pixel line. For example, FIG. 1A shows the first sub-pixel 108A, the third sub-pixel 108C of the second sub-pixel line 107B, and the fifth sub-pixel 108E of the third sub-pixel line 107C. The separation structures 110 are disposed between the anodes 104 of the first sub-pixel 108A and anodes of the third sub-pixel 108C, as well as between the third sub-pixel 108C and the fifth sub-pixel 108E. The separation structure 110 includes an upper surface 126A and a lower surface 126B. Adjacent subpixels within the same subpixel line are separated by a gap 111 between the anodes 104. For example, FIG. 1B shows the first sub-pixel 108A and the second sub-pixel 108B of the first sub-pixel line 107A. The separation structure 110 is made of a dielectric material such as Al₂O₃, or silicon containing material such as Si₃N₄, SiO₂, or other similar materials.

The OLED material 112 is disposed over and in contact with the uppermost surface 204 of the anode 104 and the upper surface 126A of the separation structure 110. The cathode 114 is disposed over the OLED material 112. The thickness of the OLED material 112 and the cathode 114 is substantially uniform in the y-direction (e.g., along the line plane). The encapsulation layer 116 is disposed over the cathode 114. As shown in FIG. 1B, the OLED material 112, the cathode 114, and the encapsulation layer 116 maintain continuity along the length of the line plane in order to apply current across each sub-pixel line. In one or more embodiments, the global encapsulation layer 118 is disposed over the encapsulation layer 116.

One or more busbars 150 are disposed on or over the substrate 102. The one or more busbars 150 are disposed adjacent to the pixel lines (e.g., first sub-pixel line 107A, second sub-pixel line 107B, and third sub-pixel line 107C). The busbars 150 provide a current to the cathodes 114, 114′ of the sub-pixel circuit 100. Although FIG. 1A depicts sub-pixel circuit 100 including four busbars 150, it is contemplated that any number of busbars can be used, including but not limited to one busbar, two busbars, three busbars, or six busbars.

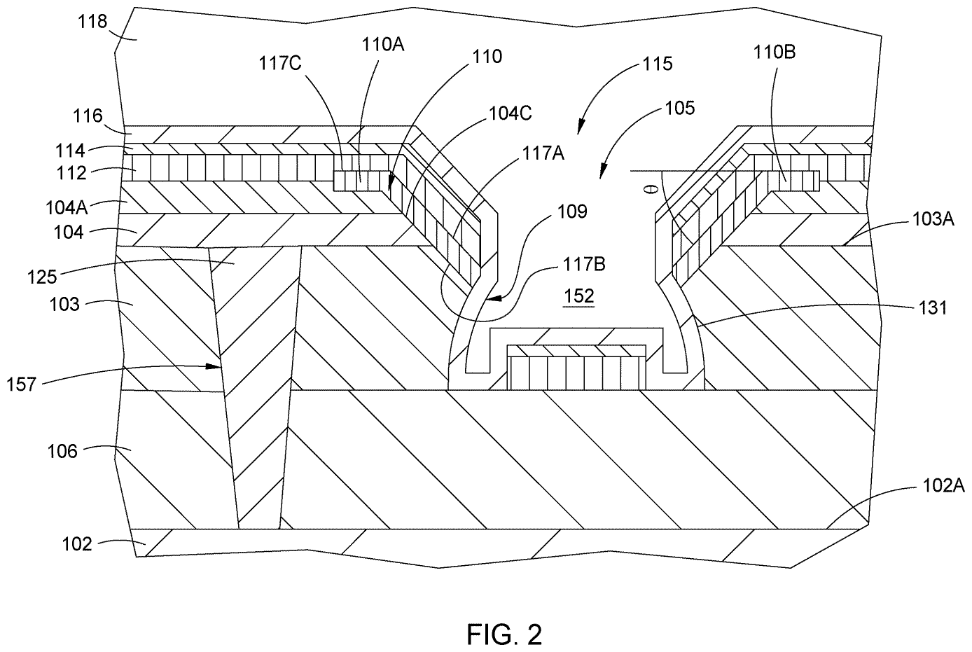

FIG. 2 is an enlarged schematic, cross-sectional view of sub-pixel circuit 100. Each separation structure 110 includes a tapered portion 117A, a bottom surface 117B, and an upper portion 117C. The upper portion 117C is disposed over a portion of the anodes 104. The tapered portion 117A is disposed over the tapered portion 104C of the anodes 104. The bottom surface 117B extends past the sidewall 131 of the isolation structure 103 to form the separation extension 109. The tapered portion 117A extends from the upper portion 117C at an angle θ of about 5° to about 35° compared to a horizontal plane. The separation extension 109 allows for the separation structure 110 to shadow a portion of the well 105 in order to control the evaporation deposition of the OLED material 112 and cathode 114. In one or more embodiments, the bottom surface 117B contacts the outer edge of the isolation structure 103. The bottom surface 117B extends over the outer portion of the anodes 104. The sidewalls 131 and the separation extensions 109 of the adjacent separation structures 110 at least partially define an area 152 within the well 105. As shown in FIG. 1C, the tapered portion 117A of the separation structure 110 enables the OLED material 112 and the cathode 114 to remain continuous in the y-direction, forming a common cathode that can be connected by horizontal bus bars outside of the active area.

A portion of the OLED material 112 is disposed over the anode 104, and the separation structure 110. In one or more embodiments, the OLED material 112 may be disposed on the tapered portion 117A and the upper portion 117C of the separation structures 110. A portion of the OLED material 112 is in direct contact with the anode 104. The cathode 114 is disposed over the OLED material 112.

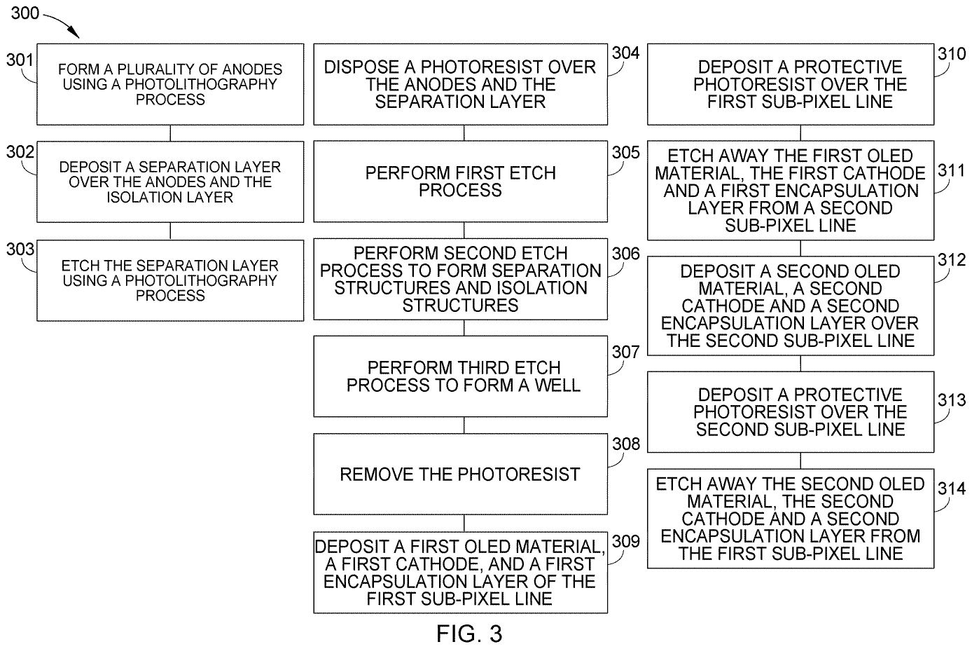

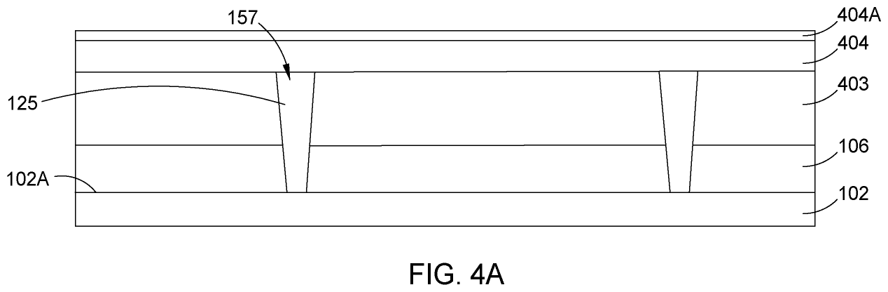

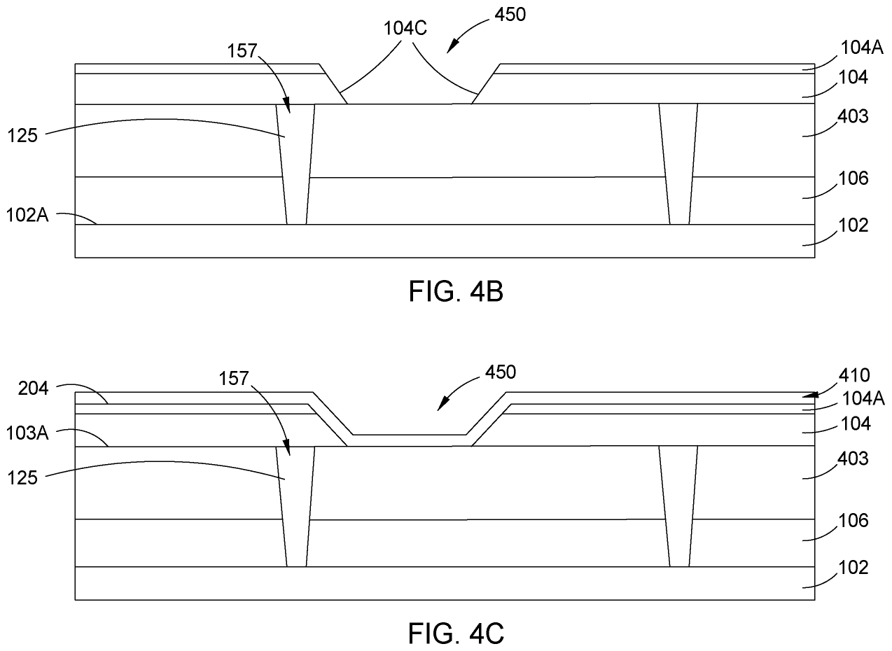

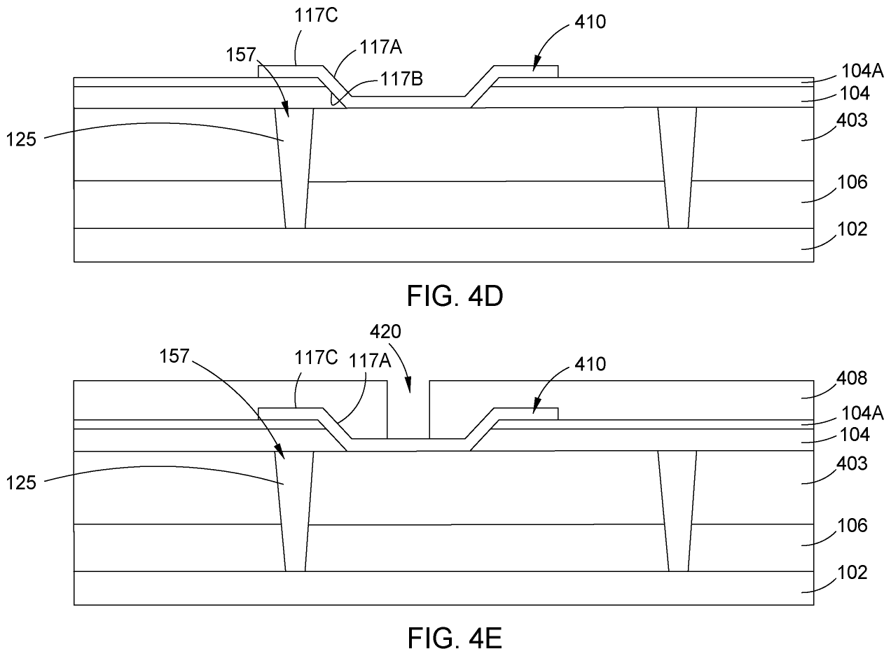

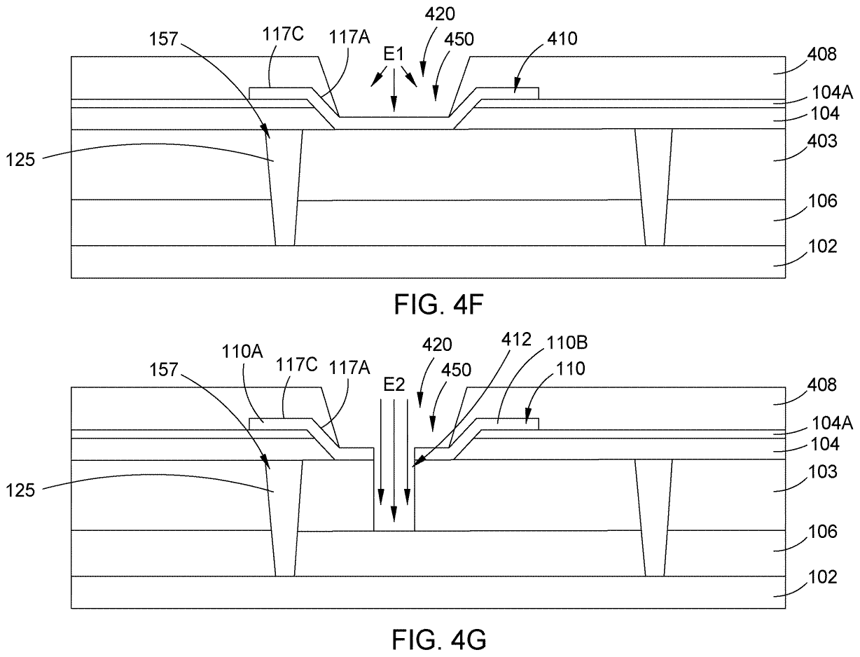

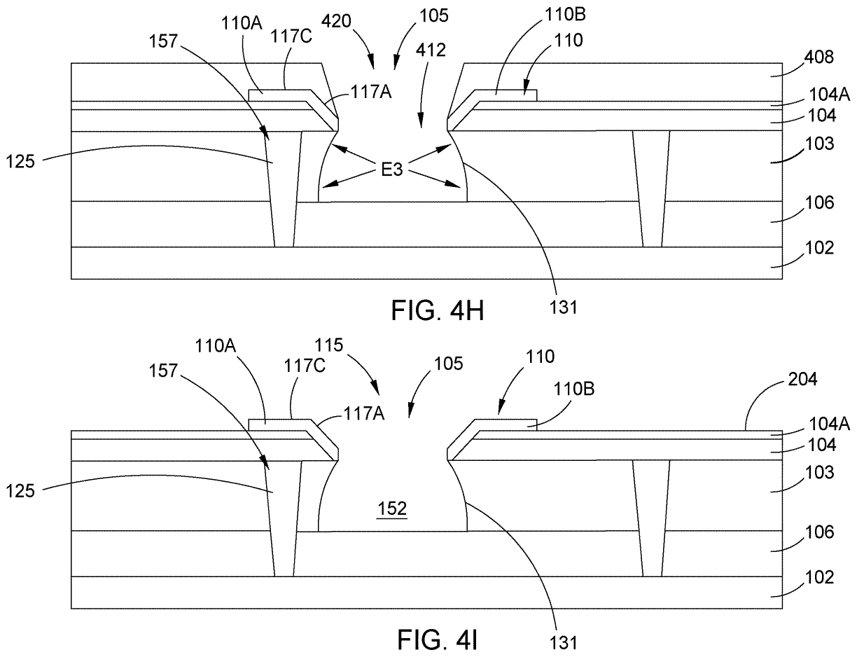

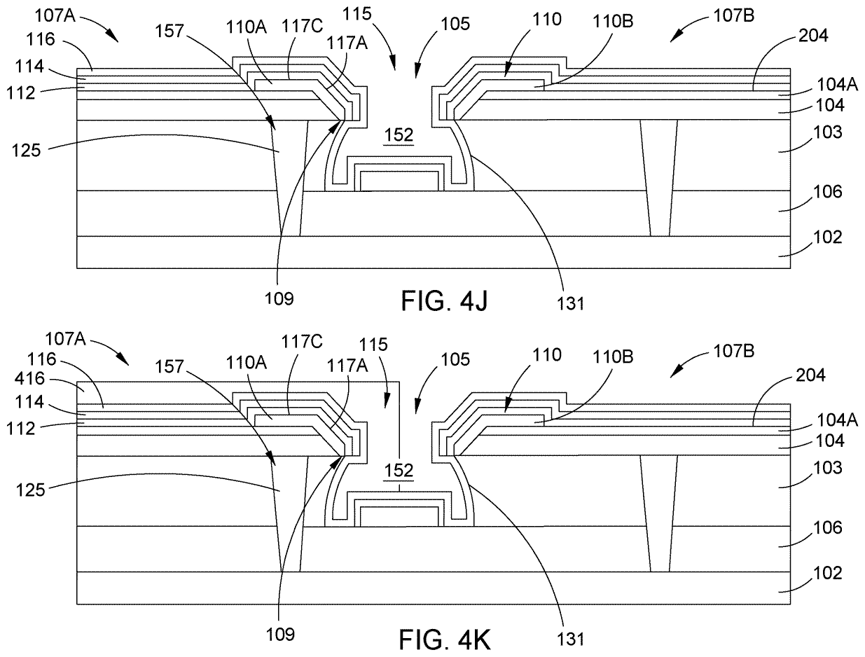

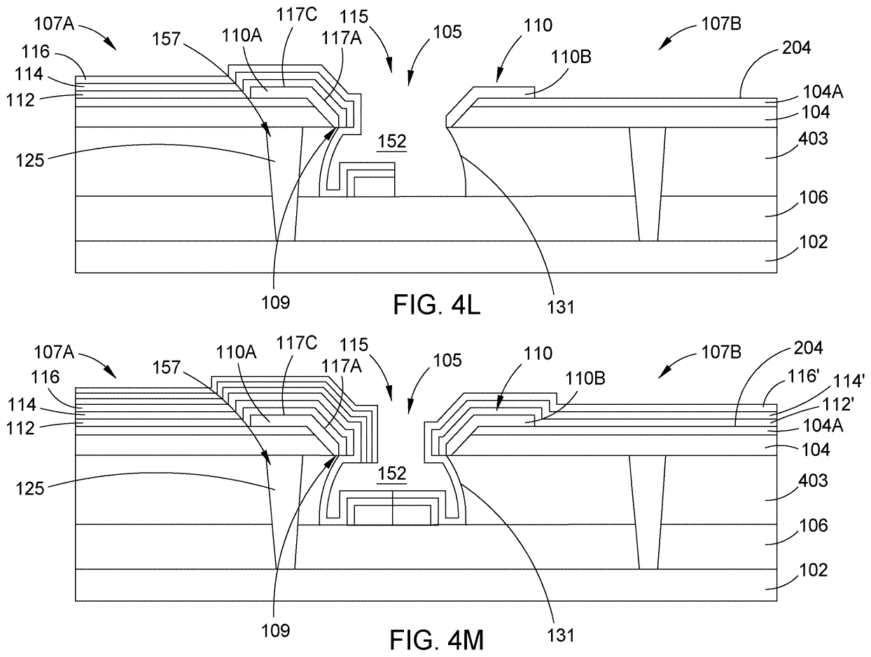

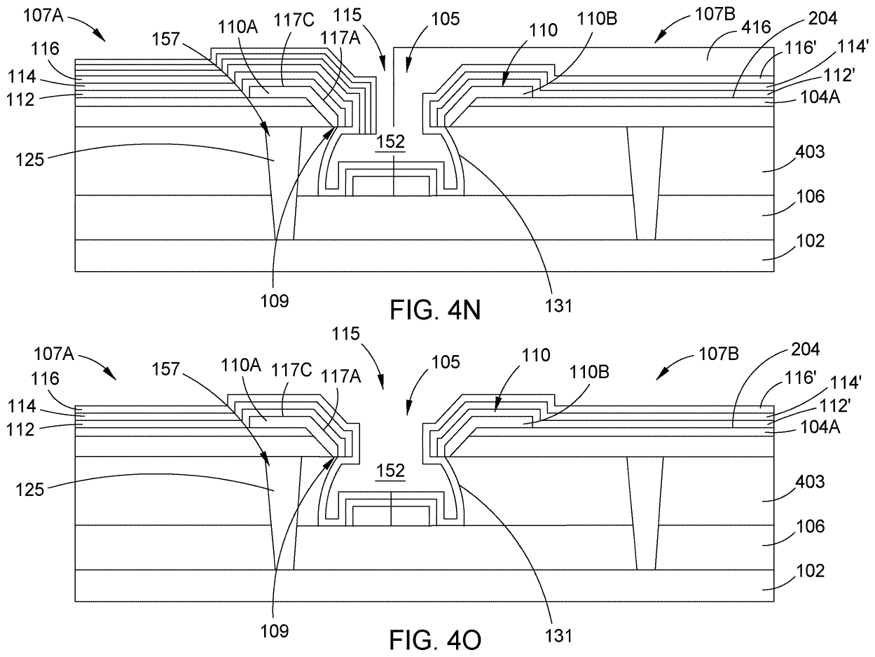

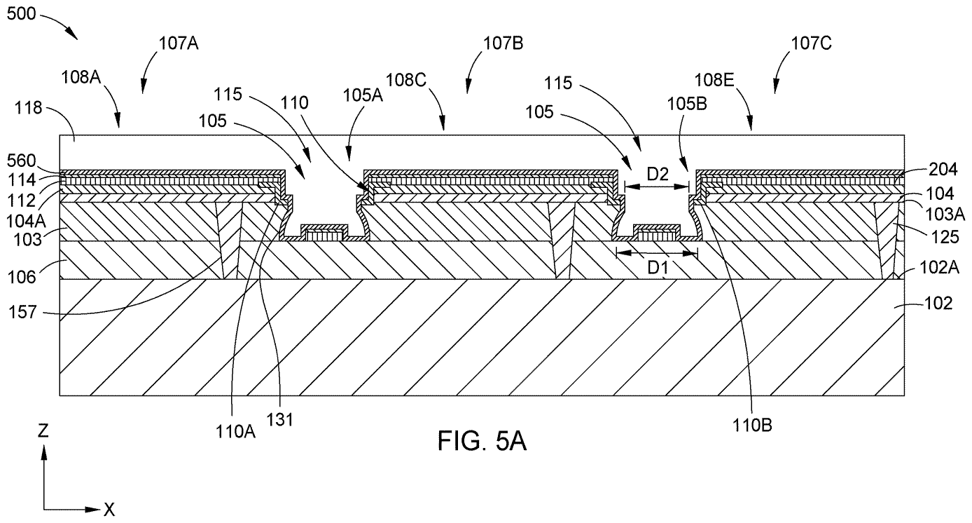

FIG. 3 is a flow diagram of a method 300 for forming a sub-pixel circuit 100 according to embodiment. FIG. 4A-4O are schematic, cross-sectional views of a substrate 102 during a method 300 for forming a sub-pixel circuit 100 according to embodiments described herein. It should be understood that although FIGS. 4A-4R depict a substrate 102 with two anodes 104, method 300 may be performed on a substrate 102 with any number of anodes 104. Prior to beginning method 300, as shown in FIG. 4A, a protective layer 106 is disposed over a substrate 102. In one or more embodiments, the protective layer 106 is deposited on an upper surface 102A of the substrate 102. An isolation layer 403 is disposed over the protective layer 106. A plurality of openings 157 are formed in the protective layer 106 and the isolation layer 403.

The protective layer 106 is formed of the protective material. The isolation layer 403 is formed of the isolation material. The isolation material and the protective material are different from one another. The isolation layer 403 has a thickness of about 0.5 μm to about 1 μm, such as a thickness of about 0.7 μm. In one or more embodiment, the isolation layer 403 is not planarized.

In one or more embodiments, which may be combined with other embodiments, the openings 157 are etched into the isolation layer 403 and the protective layer 106 to enable an electrical connection to the underlying circuits of the substrate 102. A conductive filling material (plug in via metal) is deposited within the opening 157 in order to fill the opening 157 and form the connecting portion 125. The plug in via metal includes a metal, such as tungsten or copper. In some embodiments, which may be combined with other embodiments, a planarization operation may be performed using chemical-mechanical polishing (CMP) in order to obtain a flat surface prior to depositing an anode layer 404. The openings 157 extend from an upper surface 103A of the isolation layer 403 to the upper surface 102A of the substrate 102.

One or more anode layers 404 are deposited over the isolation layer 403. The one or more anode layers 404 are deposited using chemical vapor deposition (CVD), physical vapor deposition (PVD), or atomic layer deposition (ALD). The one or more anode layers 404 include one or more anode materials, such as aluminum, a combination of aluminum and TiN, a combination of aluminum and TCO, or a TCO multilayer anode layer 404A. The TCO multilayer anode layer includes one or more anode materials such as indium tin oxide (ITO), silver (Ag), or a combination thereof. In one or more embodiment, the one or more anode layers 404 are not planarized.

At operation 301, as shown in FIG. 4B, a plurality of anodes 104 are formed using a photolithography process. During the photolithography process, a photoresist is deposited and patterned over a desired portion of the anode layer 404. The photoresist may be a positive photoresist or a negative photoresist. A positive photoresist includes portions of the photoresist, which, when exposed to electromagnetic radiation, are respectively soluble to a photoresist developer applied to the photoresist after the pattern is written into the photoresist using the electromagnetic radiation. A negative photoresist includes portions of the photoresist, which, when exposed to radiation, will be respectively insoluble to the photoresist developer applied to the photoresist after the pattern is written into the photoresist using the electromagnetic radiation. The chemical composition of the photoresist determines whether the photoresist is a positive photoresist or a negative photoresist. After the photoresist is patterned, a portion of the anode layer 404 is removed by an etching process. The etching process can include both dry etching processes and wet etching processes. The photoresist geometry causes the etching process to form a tapered portion 104C on the plurality of anodes 104. In some embodiments, the anodes 104 include a TCO multilayer anode 104A. After the etching process the photoresist is removed. After operation 304 is performed, a plurality of anodes 104 are formed over the isolation structures 103. A gap 450 electrically separates the anodes 104.

At operation 302, as shown in FIG. 4C, a separation layer 410 is deposited over anodes 104 and the isolation layer 403. The separation layer 410 is disposed on an uppermost surface 204 and tapered portion 104C of the anodes 104. The separation layer 410 is further disposed on an upper surface 103A of the isolation layer 403 within the gap 450. The separation layer 410 includes the separation material of the separation structure 110.

At operation 303, as shown in FIG. 4D, the separation layer 410 is etched using a photolithography process. During the photolithography process, a photoresist is deposited and patterned over a desired portion of the separation layer 410. The photoresist may be a positive photoresist or a negative photoresist. After the photoresist is patterned, a portion of the separation layer 410 disposed over the anodes 104 is removed by an etching process. The etching process can include both dry etching processes and wet etching processes. The etching process is a chlorine based chemistry utilizing a gas mixture of one or more of boron trichloride (BCl₃), chlorine (Cl₂), oxygen (O₂), and argon (Ar). The separation layer 410 is disposed over the upper surface 103A of the isolation layer 403 within the gap 450 and extends over a portion of the anodes 104. The separation layer 410 includes a tapered portion 117A, a bottom surface 117B and an upper portion 117C. The upper portion 117C is disposed over a portion of the uppermost surface 204 of the anodes 104. The tapered portion 117A is disposed between the portion of the separation layer 410 disposed on the uppermost surface 204 of the anodes 104 and the portion of the separation layer 410 disposed on the upper surface 103A of the isolation layer 403. After the etching process, the photoresist is removed.

At operation 304, as shown in FIG. 4E, a photoresist 408 is disposed over the anodes 104 and the separation layer 410. An opening 420 along the y-direction is formed in the photoresist 408 over a center portion of the separation layer 410 disposed within the gap 450. The opening 420 exposes a middle portion of the separation layer 410 in the y-direction. In some embodiments, the opening 420 is in a range of about 100 nm to about 700 nm, such as in a range of about 200 nm to about 500 nm for CMOS sub-pixel circuits. In other embodiments, the opening 420 is about 200 nm to about 800 nm, such as about 300 nm to about 500 nm for glass based sub-pixel circuits.

At optional operation 305, as shown in FIG. 4F, a first etching process E1 is performed. The first etching process E1 is the first operation in a three-operation reactive ion etching (RIE) process. During the first etching process E1, an aluminum oxide (Al₂O₃) chlorine (Cl) based dry etch is used to widen opening 420 formed in the photoresist 408. The first etching process E1 is an anisotropic process. The separation layer 410 may be slightly etched into as well.

At operation 306, as shown in FIG. 4G, a second etching process E2 is performed to form separation structures 110 and isolation structures 103. The second etching process E2 is the second operation in a three operation reactive ion etching (RIE) process. During the second etching process E2, an etchant is used vertically etch a channel 412 through the separation layer 410 and into the isolation layer 403. The etchant includes etchants such as a fluorine (F) based dry etch. The second etching process E2 is an anisotropic process. The etching process E2 is stopped before channel 412 reaches the protective layer 106. The second etching process E2 forms adjacent the first separation structures 110A, the second separation structure 110B and the isolation structures 103. The channel 412 separates the first separation structure 110A from the second separation structure 110B and separates adjacent isolation structures 103. The channel 412 has a width within a range of about 200 nm to about 600 nm, such as a width within a range of about 250 nm to about 500 nm.

At operation 307, as shown in FIG. 4H, a third etching process E3 is performed to form a well 105. The third etching process E3 is the third operation in a three operation reactive ion etching (RIE) process. During the third etching process E3, an etchant is used to selectively etch the isolation structures 103. The isolation structures 103 are formed of the isolation material with the first etch rate. The separation structures 110 are formed of the separation material having the second etch rate. The first etch rate is different from the second etch rate. The different etch rates of the isolation material and the separation material cause the isolation structures 103 to be widened at a greater rate than the separation structures 110 during the third etching process, forming the well 105. The etchant includes etchants such as silver potassium based wet etchant, or silver iodine based wet etchant.

The third etching process E3 is an isotropic process. The third etching process selectively etched the isolation structures 103, while avoiding etching into the separation structures 110 and the protective layer 106 due to the difference in etch selectivity. The protective layer 106 has a third etch rate. The third etch rate is different from the first etch rate. In some embodiment, the second etch rate is the same or approximately the same as the third etch rate. After the third etching process E3 is performed, the sidewalls 131 of the isolation structures 103 are separated by a distance D1, as shown in FIG. 1B. The first separation structure 110A, the second separation structure 110B, and isolation structures 103 partially define the area 152 of a well 105. After the third etching process E3 is performed, the first separation structure 110A and the second separation structure 110B are separated by a distance D2, as shown in FIG. 1B. In one or more embodiments, the distance D2 is from about 400 nm to about 800 nm.

At operation 308, as shown in FIG. 4I, the photoresist 408 is removed. After operation 310 is performed, a portion of the uppermost surface 204 of the anodes 104 is exposed, while a portion of the anodes 104 remain covered by the separation structures 110.

At operation 309, as shown in FIG. 4J, the first OLED material 112, the first cathode 114, and the first encapsulation layer 116 of the first sub-pixel line 107A are deposited. The first OLED material 112, first cathode 114, and first encapsulation layer 116 are deposited using CVD or ALD for the deposition of the encapsulation layer 116. The first OLED material 112 may include an HIL material. The shadowing of the adjacent separation extensions 109 within the area 152 provides for a break in the first OLED material 112 and the first cathode 114 along the x-direction (e.g., the pixel plane) in order to differentiate the different colored pixels. The first OLED material 112 and the first cathode 114 separate (e.g., may be non-continuous) along the x-direction. The first OLED material 112 and first cathode 114 may maintain continuity along the y-direction (e.g., the line plane), e.g., the first OLED material 112 and the first cathode 114 are disposed over the separations structures 110. The total thickness of the first OLED material 112 and the first cathode 114 is from about 80 nm to about 150 nm.

At operation 310, as shown in FIG. 4K, a protective photoresist 416 is deposited over the first sub-pixel line 107A. The protective photoresist 416 may be a positive photoresist or a negative photoresist. The protective photoresist 416 extends over the anode 104 and the first separation structure 110A within the first sub-pixel line 107A. The protective photoresist 416 extends into the opening 115 of the well 105. The protective photoresist 416 covers the first OLED material 112 and the first cathode 114 disposed over the first separation structure 110A and protects a portion of the first OLED material 112 and the first cathode 114 within the well 105. The protective photoresist 416 does not cover the first OLED material 112 and the first cathode 114 disposed over the second separation structure 110B.

At operation 311, as shown in FIG. 4L, the first OLED material 112, the first cathode 114, and the first encapsulation layer 116 disposed over the second sub-pixel line 107B are etched away. The first OLED material 112, the first cathode 114, and the first encapsulation layer 116 are protected by the protective photoresist 416 during the etching process. After the etching process is completed, the protective photoresist 416 is removed and the first OLED material 112, the first cathode 114, and first encapsulation layer 116 that was covered by the protective photoresist 416 during the etching process remains.

At operation 312, as shown in FIG. 4M, a second OLED material 112′, a second cathode 114′, and a second encapsulation layer 116′ of the second sub-pixel line 107B are deposited. The second OLED material 112′, second cathode 114′, and second encapsulation layer 116′ are deposited using CVD or ALD. The second OLED material 112′ may include an HIL material. The second OLED material 112′ may be a different color than the first OLED material 112. The shadowing of the adjacent separation extensions 109 provides within the area 152 provides for an electrical break in the second OLED material 112′ and the second cathode 114′. The second OLED material 112′ and the second cathode 114′ separate (e.g., may be non-continuous) along the x-direction. The second OLED material 112′ and second cathode 114′ maintain continuity along the y-direction, e.g., the second OLED material 112′ and the second cathode 114′ are disposed over the separations structures 110. The total thickness of the second OLED material 112′ and the second cathode 114′ is from about 80 nm to about 150 nm.

At operation 313, as shown in FIG. 4N, a protective photoresist 416 is deposited over the second sub-pixel line 107B. The protective photoresist 416 extends over the anode 104 and the second separation structure 110B within the second sub-pixel line 107B. The protective photoresist 416 extends into the opening 115 of the well 105. The protective photoresist covers the second OLED material 112′ and the second cathode 114′ disposed over the second separation structure 110B and protects a portion of the second OLED material 112′ and the second cathode 114′ within the area 152. The protective photoresist does not cover the second OLED material 112′ and the second cathode 114′ disposed over the first separation structure 110A and the first sub-pixel line 107A.

At operation 314, as shown in FIG. 4O, the second OLED material 112′, the second cathode 114′, and the second encapsulation layer 116′ disposed over the first sub-pixel line 107A are etched away. The second OLED material 112′, the second cathode 114′, and the second encapsulation layer 116′ disposed over the first sub-pixel line 107A are etched away so that the encapsulation layer 116 of the first sub-pixel line 107A is exposed. The second OLED material 112′, the second cathode 114′, and the second encapsulation layer 116′ of the second sub-pixel line 107B are protected by the protective photoresist 416 during the etching process. After the etching process is completed, the protective photoresist 416 is removed and the second OLED material 112′ and the second cathode 114′ that was covered by the protective photoresist 416 during the etching process remains. After the protective photoresist 416 is removed, the first sub-pixel line 107A includes the first OLED material 112, the first cathode 114, and the first encapsulation layer 116 of the first sub-pixel line 107A, and the second sub-pixel line 107B includes the second OLED material 112′, the second cathode 114′, and the second encapsulation layer 116′ of the second sub-pixel line 107B.

The first encapsulation layer 116 and second encapsulation layer 116′ extend over the first cathode 114 and the second cathode 114′ disposed over the anode 104 and the separation structures 110. The first encapsulation layer 116 and second encapsulation layer 116′ extend into the wells 105 and contacts a bottom surface of the separation extension 109, as well as the sidewalls 131 of the isolation structures 103. Additionally, the encapsulation layer 116 is disposed over the first OLED material 112, the second OLED material 112′, the first cathode 114, and the second cathode 114′ within the well 105. The encapsulation layer 116 includes the non-conductive inorganic material, such as aluminum oxide (Al₂O₃), a silicon-containing material, such as SiO₂ or Si₃N₄, or a conductive inorganic material, such as a transparent conductive oxide, such as ITO, ZnO, AZO, or SnO₂, deposited by a conformal deposition method such as atomic layer deposition (ALD). When the encapsulation layer is a conductive inorganic material, the encapsulation layer may function to electrically connect the cathodes to form an assistant cathode. In one or more embodiments, a global encapsulation layer 118 may optionally be disposed over the encapsulation layer 116. The global encapsulation layer 118 layer fills the openings 115 of the well 105 and covers the entirety of the sub-pixel circuit 100.

Other components of the sub-pixel circuit 100 are protected during the various etching processes by various etch stops. The dielectric encapsulation layer 116 is removed by dry etching (e.g. BCL₃) or by wet etching (e.g. BHF). The sub-pixel circuit 100 may be protected from the etchant of the encapsulation layer using a metallic cathode layer. The cathode 114 is etched by a wet etch process using (e.g. KI). The sub-pixel circuit 100 may be protected from the etchant of the cathode 114 by either the OLED material 112, the previously deposited encapsulation layer 116, or the anode 104. The OLED material 112 is removed a plasma (e.g., O₂) or an organic solvent. These removal materials do not affect the encapsulation layer 116 or the anode 104.

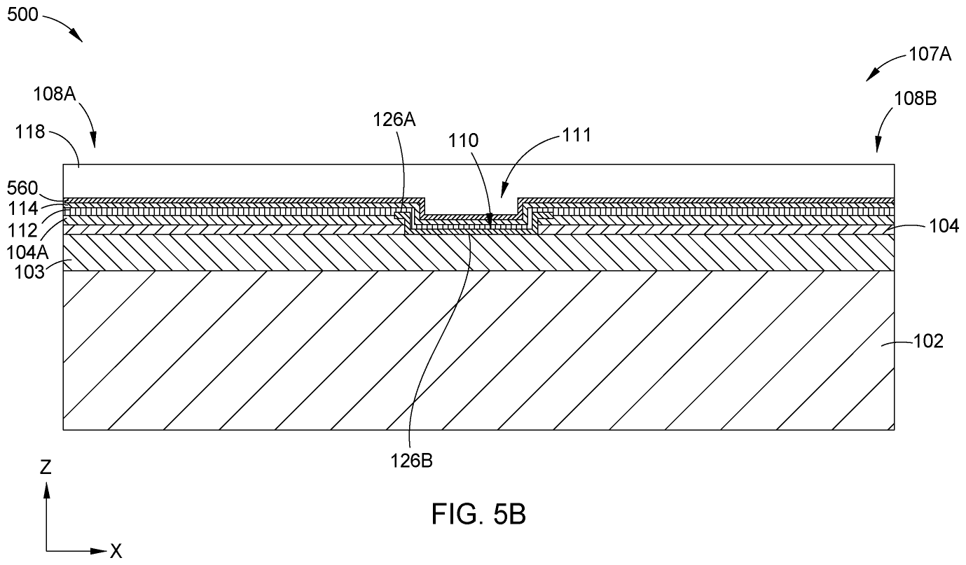

FIG. 5A is a schematic, cross-sectional view of a sub-pixel circuit 500, according to one or more embodiments. The cross-sectional view of FIG. 5A is taken along section line 1B-1B of FIG. 1A (e.g., a pixel plane or x-direction). FIG. 5B is a schematic, cross-sectional view of a sub-pixel circuit 500 according to embodiments. The cross-sectional view of FIG. 5B is taken along section line 1C-1C of FIG. 1A (e.g., a line plane or y-direction). The sub-pixel circuit 500 can be used in place of the sub-pixel circuit 100. Identical reference numerals have been used, where possible, to designate identical elements that are common to the figures.

The sub-pixel circuit 500 includes an assistant cathode 560. The assistant cathode 560 is conformally disposed over the cathode 114. In some embodiments, the assistant cathode 560 is conformally disposed on an upper surface of the cathode 114. The assistant cathode 560 is deposited over the cathode 114 using atomic layer deposition. The assistant cathode 560 is made from an assistant cathode material. The assistant cathode material may include a TCO material, such as one or more indium gallium zinc oxide (IGZO) layers, indium zinc oxide (IZO) layers zinc oxide (ZnO), aluminum doped zinc oxide (AZO), indium tin oxide (ITO) or similar material. In one more embodiments, the TCO cathode has a thickness from about 50 nm to about 100 nm. In some embodiments, an encapsulation layer 116 may be disposed over the assistant cathode 560. The assistant cathode 560 forms a cathode connection and bridges any electrical discontinuities of the cathode 114 that may exist in the y-direction, as shown in FIG. 5B. Furthermore, the assistant cathode 560 enables the connection of horizontal bus bars outside of the active area and bridges the electrical discontinuities in the x-direction, enabling the use of non-line-type sub-pixel arrangements, such as a RBG quad type to honeycomb type sub-pixel arrangements. The assistant cathode 560 may act as an encapsulation layer for the OLED material 112. In some embodiments, an encapsulation layer, such as encapsulation layer 116, may be disposed over the assistant cathode 560.

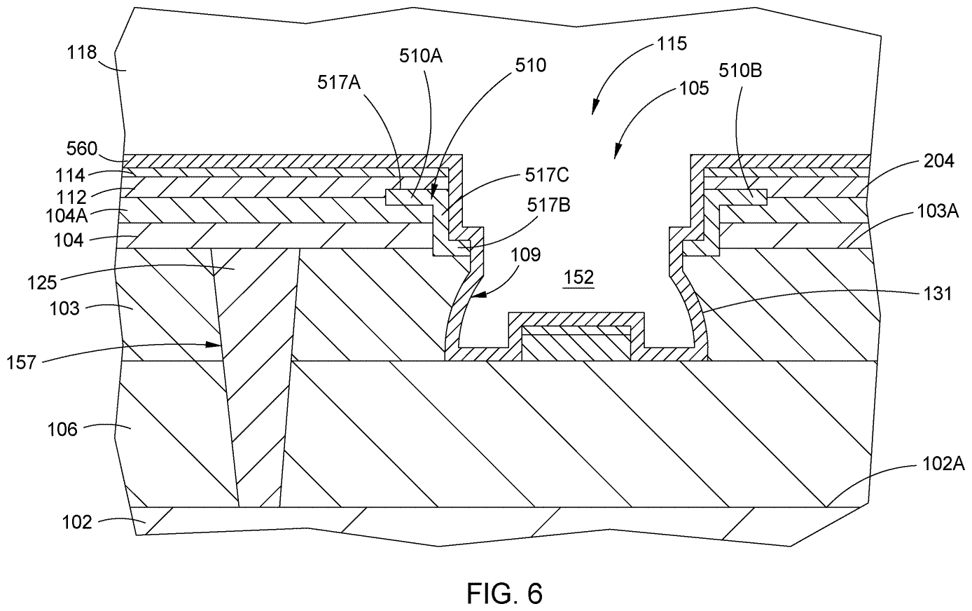

FIG. 6 is a close up schematic, cross-sectional view of sub-pixel circuit 500. Each separation structure 510 includes an upper portion 517A, a lower portion 517B, and an intermediate portion 517C spanning between the upper portion 517A and the lower portion 517B. In some embodiments, the intermediate portion 517C is vertical (e.g., at an angle of 90°) between the upper portion 517A and the lower portion 517B. In other embodiments, the intermediate portion 517C is angled between the upper portion 517A and the lower portion 517B, where the angle is about 30° to about 90°. The lower portion 517B extends past the sidewall 131 of the isolation structure 103 to form the separation extension 109. The separation extension 109 allows for the separation structure 510 to shadow a portion of the well 105. In one or more embodiments, the lower portion 517B contacts the outer edge of the isolation structure 103. The upper portion 517A extends over a portion of the uppermost surface 204 of the anodes 104. The sidewalls 131 and the separation extensions 109 of the adjacent separation structures 510 at least partially define an area 152 within the well 105.

A portion of the OLED material 112 is disposed over the anode 104, the separation structure 510, and inside the well 105. In one or more embodiments, the OLED material 112 may be disposed over the intermediate portion 517C and the upper portion 517A of the separation structures 510. A portion of the OLED material is in direct contact with the anode 104. The cathode 114 is disposed over the OLED material 112.

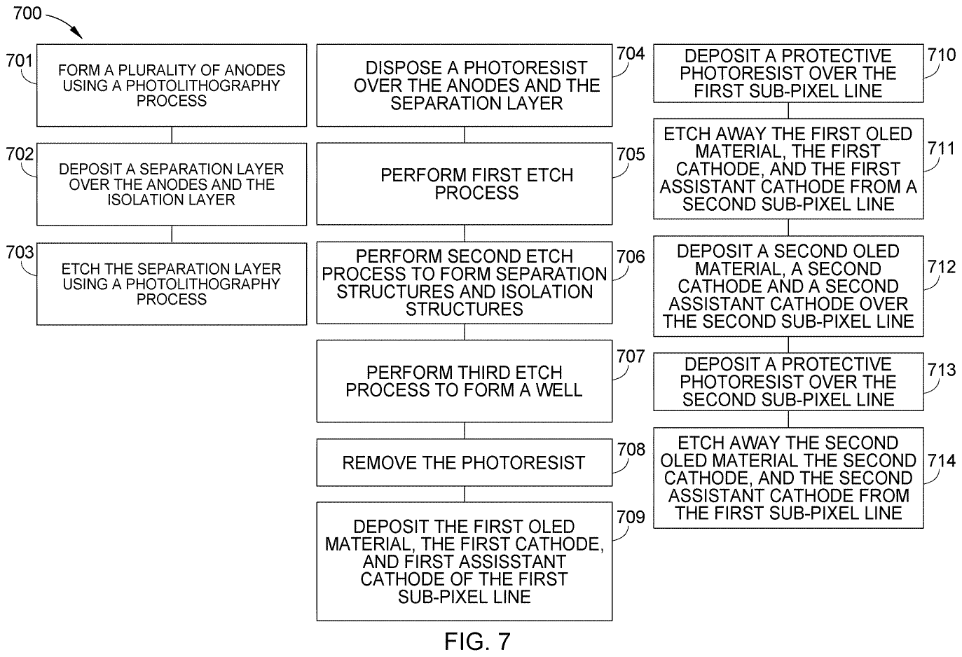

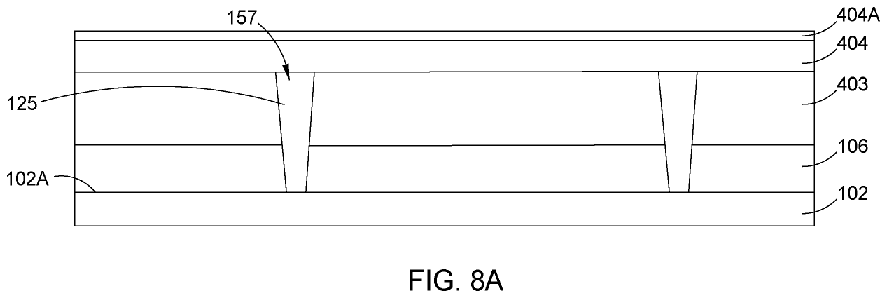

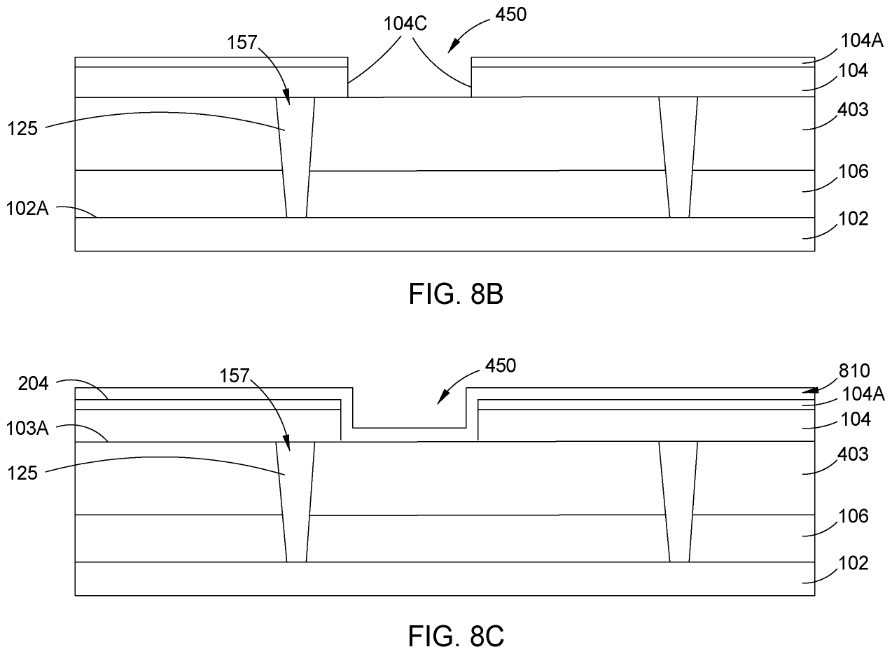

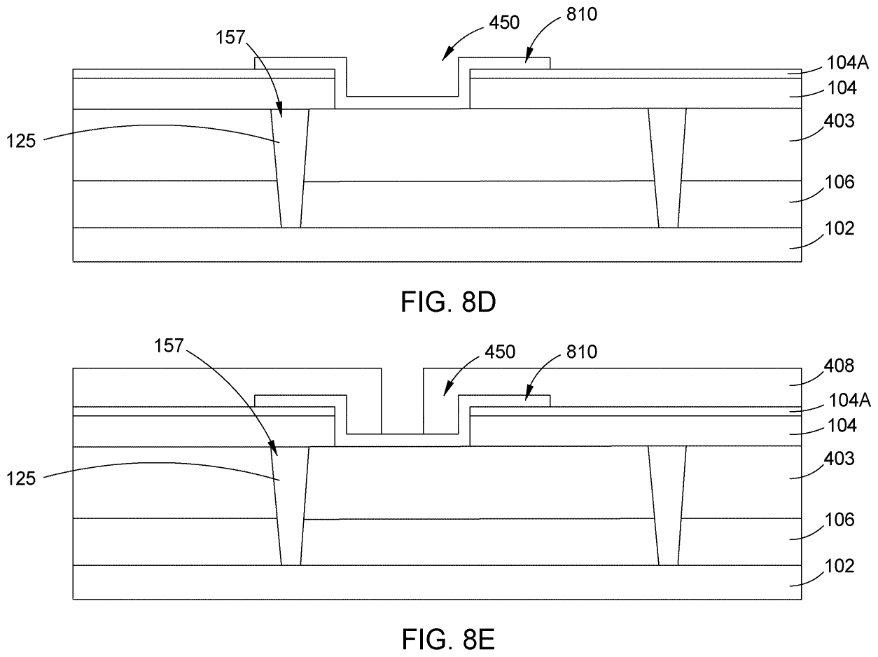

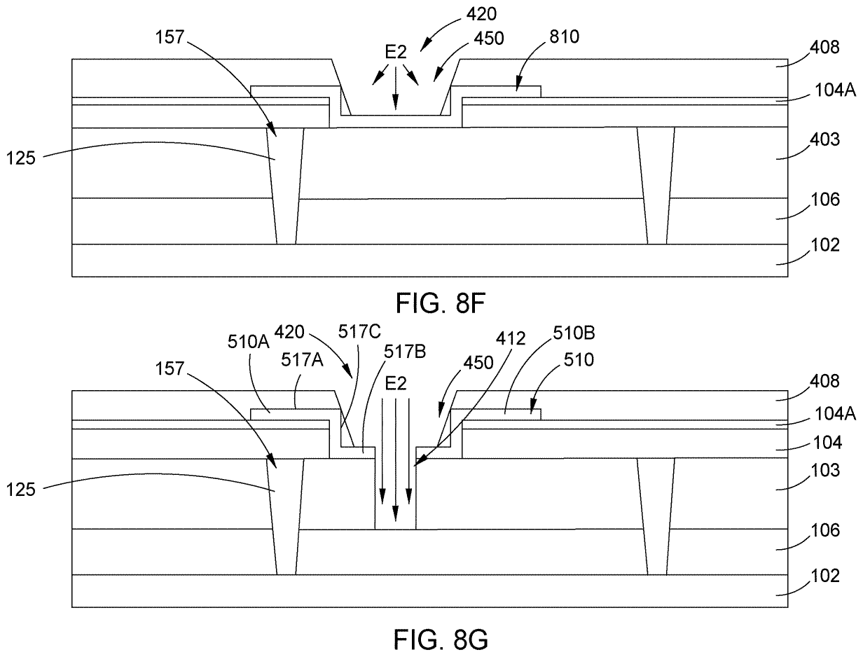

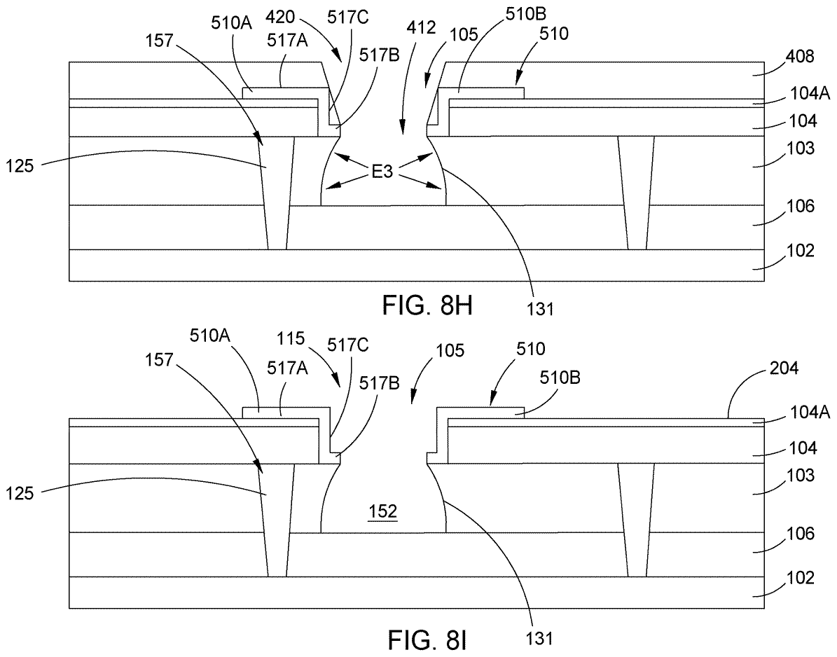

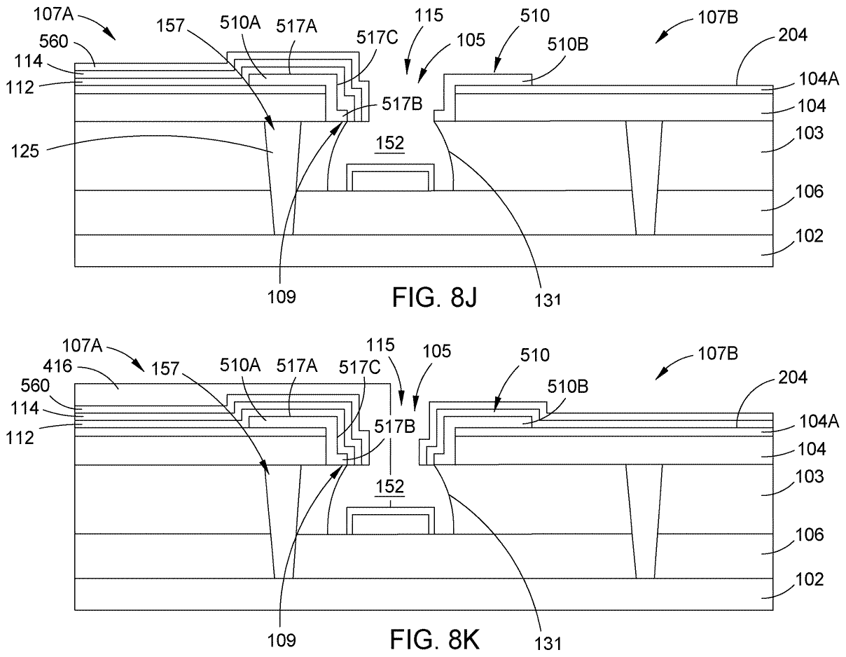

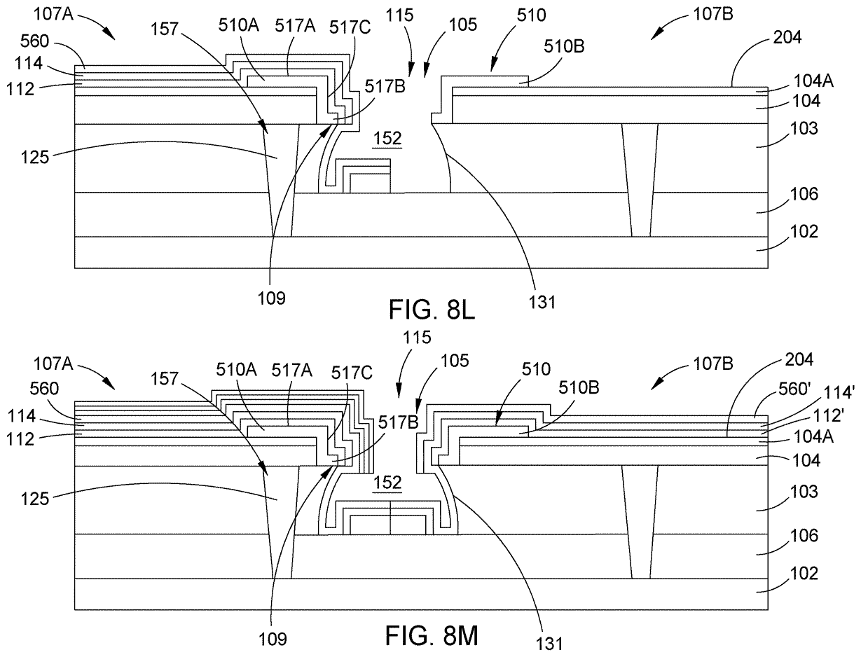

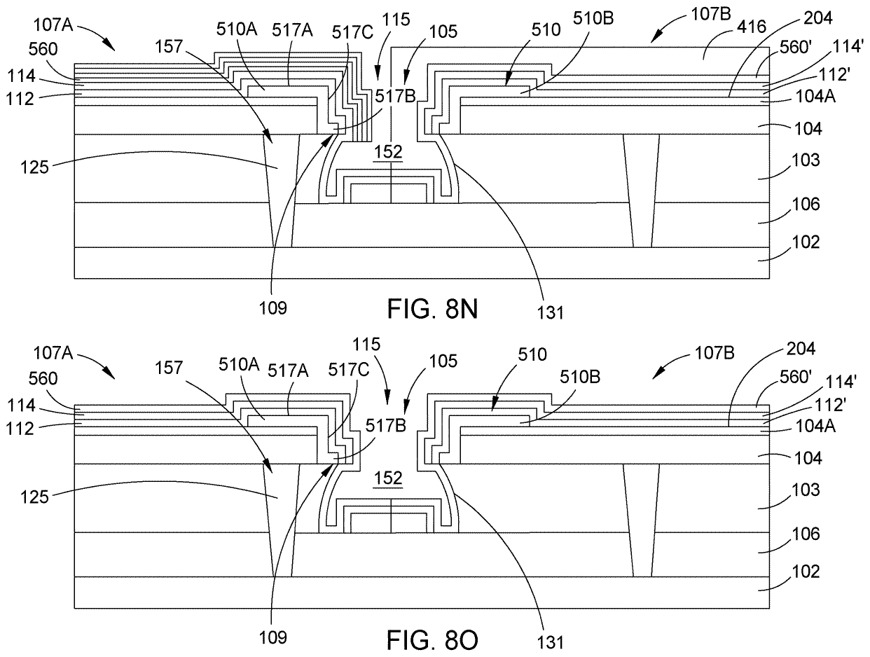

FIG. 7 is a flow diagram of a method 700 for forming a sub-pixel circuit 500. FIG. 8A-8S are schematic, cross-sectional views of a substrate 102 during a method 700 for forming a sub-pixel circuit 500. It should be understood that although FIGS. 8A-8S depict a substrate with two anodes, method 700 may be performed on a substrate with any number of anodes. Prior to beginning method 700, as shown in FIG. 8A, a protective layer 106 is disposed over a substrate 102. In one or more embodiments, the protective layer 106 is deposited on an upper surface 102A of the substrate 102. An isolation layer 403 is disposed over the protective layer 106. A plurality of openings 157 are formed in the protective layer 106 and the isolation layer 403.

The protective layer 106 is formed of a protective material. The isolation layer 403 is formed of an isolation material. The isolation material and the protective material are different from one another. The isolation layer 403 has a thickness of about 0.3 μm to about 1 μm, such as a thickness of about 0.4 μm to about 0.5 μm.

In one or more embodiments, the openings 157 are etched into the isolation layer 403 and the protective layer 106 to enable an electrical connection to the underlying circuits of the substrate 102. A conductive filling material (plug in via metal) is deposited within the opening 157 in order to fill the opening 157 and form the connecting portion 125. The plug in via metal includes a metal material, such as tungsten or copper. In some embodiments, a planarization operation may be performed using chemical-mechanical polishing (CMP) in order to obtain a flat surface prior to depositing an anode layer 404. The openings 157 extend from an upper surface of the isolation layer 403 to the upper surface 102A of the substrate 102.

One or more anode layers 404 are deposited over the isolation layer 403. The one or more anode layers 404 are deposited using chemical vapor deposition (CVD), physical vapor deposition (PVD), or atomic layer deposition (ALD). The one or more anode layers 404 include one or more anode materials, such as aluminum, a combination of aluminum and TiN, a combination of aluminum and TCO, or a TCO multilayer anode layer 404A. The TCO multilayer anode layer includes one or more anode materials such as indium tin oxide (ITO), silver (Ag), or a combination thereof. In one or more embodiment, the one or more anode layers 404 are not planarized.

At operation 701, as shown in FIG. 8B, a plurality of anodes 104 are formed using a photolithography process. During the photolithography process, a photoresist is deposited and patterned over a desired portion of the anode layer 404. The photoresist may be a positive photoresist or a negative photoresist. After the photoresist is patterned, a portion of the anode layer 404 is removed by an etching process. The etching process can include both dry etching processes and wet etching processes. In some embodiments, the anodes 104 include a TCO multilayer anode 104A. After the etching process, the photoresist is removed. After operation 704 is performed, a plurality of anodes 104 are formed over the isolation structures 103. A gap 450 separates the anodes 104.

At operation 702, as shown in FIG. 8C, a separation layer 810 is deposited over anodes 104 and the isolation layer 403. The separation layer 810 is disposed on an uppermost surface 204 and an outer portion of the anodes 104. The separation layer 810 is further disposed on an upper surface 103A of the isolation layer 403 within the gap 450. The separation layer 810 includes the separation material of the separation structure 510. The difference in the isolation material and the separation material results in different etch rates such that the separation structure 510 has the separation extension 109 that extends past a sidewall 131 of the isolation layer 403, as described herein.

At operation 703, as shown in FIG. 8D, the separation layer 810 is etched using a photolithography process. During the photolithography process, a photoresist is deposited and patterned over a desired portion of the separation layer 810. The photoresist may be a positive photoresist or a negative photoresist. After the photoresist is patterned, a portion of the separation layer 810 disposed over the anodes 104 is removed by an etching process. The etching process can include both dry etching processes and wet etching processes. The separation layer 810 is disposed over the upper surface 103A of the isolation layer 403 within the gap 450 and extends over a portion of the anodes 104. After the etching process, the photoresist is removed.

At operation 704, as shown in FIG. 8E, a photoresist 408 is disposed over the anodes 104 and the separation layer 810. An opening 420 along the y-direction is formed in the photoresist 408 over a center portion of the separation layer 810 disposed within the gap 450. The opening 420 exposes a middle portion of the separation layer 810 in the y-direction. The opening 420 is in a range of about 100 nm to about 700 nm, such was in a range of about 200 nm to about 500 nm. In other embodiments, the opening 420 is about 200 nm to about 800 nm, such as about 300 nm to about 500 nm for glass based sub-pixels circuits.

At operation 705, as shown in FIG. 8F, a first etching process E1 is performed. The first etching process E1 is the first operation in a three operation reactive ion etching (RIE) process. During the first etching process E1, an aluminum oxide (Al₂O₃) chlorine (Cl) based dry etch is used to widen opening 420 formed in the photoresist 408. The first etching process E1 is an anisotropic process. The separation layer 810 may be slightly etched into as well.

At operation 706, as shown in FIG. 8G, a second etching process E2 is performed to form separation structures 510 and isolation structures 103. The second etching process E2 is the second operation in a three operation reactive ion etching (RIE) process. During the second etching process E2, an etchant is used vertically etch a channel 412 through the separation layer 810 and into the isolation layer 403. The etchant includes etchants such as a silicon monoxide (SiO) fluorine (F) based dry etch. The second etching process E2 is an anisotropic process. The etching process E2 is stopped before channel 412 reaches the protective layer 106. The second etching process E2 forms adjacent the first separation structures 510A, the second separation structure 510B, and the isolation structures 103. The channel 412 separates the first separation structure 510A from the second separation structure 510B and separates adjacent isolation structures 103. The channel 412 has a width within a range of about 200 nm to about 500 nm such as a width within a range of about 250 nm to about 400 nm.

Each separation structure 510 includes an upper portion 517A, a lower portion 517B, and an intermediate portion 517C spanning between the upper portion 517A and the lower portion 517B. The lower portion 517B extends past the sidewall 131 of the isolation structure 103 to form the separation extension 109. In one or more embodiments, the lower portion 517B contacts the outer edge of the isolation structure 103. The upper portion 517A extends over a portion of the uppermost surface of the tapered portion 104C of the anodes 104.

At operation 707, as shown in FIG. 8H, a third etching process E3 is performed to form a well 105. The third etching process E3 is the third operation in a three operation reactive ion etching (RIE) process. During the third etching process E3, an etchant is used selectively etch the isolation structures 103. The isolation structures 103 are formed of the isolation material with the first etch rate. The separation structures 510 is formed of the separation material having the second etch rate. The different etch rates of the isolation material and the separation material causes the isolation structures 103 to be widened at a greater rate than the separation structures 510 during the third etching process, forming the well 105. The etchant includes etchants such as silver potassium based wet etchant, or silver iodine based wet etchant.

The third etching process E3 is an isentropic process. The third etching process selectively etched the isolation structures 103, while avoiding etching into the separation structures 510 and the protective layer 106. After the third etching process E3 is performed, the sidewalls 131 of the isolation structures 103 are separated by a distance D1. The first separation structure 510A, the second separation structure 510B, and isolation structures 103 partially define the area 152. After the third etching process E3 is performed, the first separation structure 510A and the second separation structure 510B are separated by a distance D2. In one or more embodiments, the distance D2 is from about 400 nm to about 800 nm.

At operation 708, as shown in FIG. 8I, the photoresist 408 is removed. After operation 310 is performed, a portion of the uppermost surface 204 of the anodes 104 is exposed, while a portion of the anodes 104 remain covered by the separation structures 110.

At operation 709, as shown in FIG. 8J, the first OLED material 112, the first cathode 114, and first assistant cathode 560 of the first sub-pixel line 107A are deposited. The first OLED material 112, first cathode 114, and first encapsulation layer 116 are deposited using CVD or ALD or deposition of the encapsulation layer 116. The first OLED material 112 may include an HIL material. The separation extension 109 allows for the separation structure 510 to shadow a portion of a well 105. The shadowing of the adjacent separation extensions 109 within the area 152 provides for a break in the first OLED material 112 and the first cathode 114 along the x-direction. The first OLED material 112 and the first cathode 114 separate (e.g., may be non-continuous) along the x-direction. The first OLED material 112 and first cathode 114 may maintain continuity along the y-direction, e.g., the first OLED material 112 and the first cathode 114 are disposed over the separations structures 110. The total thickness of the first OLED material 112 and the first cathode 114 is from about 80 nm to about 150 nm.

At operation 710, as shown in FIG. 8K, a protective photoresist 416 is deposited over the first sub-pixel line 107A. The protective photoresist may be a positive photoresist or a negative photoresist. The protective photoresist 416 extends over the anode 104 and the first separation structure 110A within the first sub-pixel line 107A. The protective photoresist 416 extends into the opening 115 of the well 105. The protective photoresist 416 covers the first OLED material 112 and the first cathode 114 disposed over the first separation structure 110A and protects a portion of the first OLED material 112 and the first cathode 114 within the well 105. The protective photoresist 416 does not cover the first OLED material 112 and the first cathode 114 disposed over the second separation structure 110B.

At operation 711, as shown in FIG. 8L, the first OLED material 112, the first cathode 114, and the first assistant cathode 560 disposed over the second sub-pixel line 107B are etched away. The first OLED material 112, the first cathode 114, and the first assistant cathode 560 are protected by the protective photoresist 416 during the etching process. After the etching process is completed, the protective photoresist 416 is removed and the first OLED material 112, the first cathode 114, and the first assistant cathode 560 that was covered by the protective photoresist 416 during the etching process remains.

At operation 712, as shown in FIG. 8M, a second OLED material 112′ of the second sub-pixel line 107B, a second cathode 114′, and a second assistant cathode 560′ of the second sub-pixel line 107B are deposited. The second OLED material 112′, second cathode 114′, and second encapsulation layer 116′ are deposited using CVD or ALD. The second OLED material 112′ may include an HIL material. The second OLED material 112′ may be a different color than the first OLED material 112. The second OLED material 112′ may include an HIL material. The shadowing of the adjacent separation extensions 109 provides within the area 152 provides for an electrical break in the second OLED material 112′ and the second cathode 114′. The second OLED material 112′ and the second cathode 114′ separate (e.g., may be non-continuous) along the x-direction. The second OLED material 112′ and second cathode 114′ maintain continuity along the y-direction, e.g., the second OLED material 112′ and the second cathode 114′ are disposed over the separation structures 110. The total thickness of the second OLED material 112′ and the second cathode 114′ is from about 100 nm to about 150 nm.

At operation 713, as shown in FIG. 8N, a protective photoresist 416 is deposited over the second sub-pixel line 107B. The protective photoresist 416 extends over the anode 104 and the second separation structure 110B within the second sub-pixel line 107B. The protective photoresist 416 extends into the opening 115 of the well 105. The protective photoresist covers the second OLED material 112′ and the second cathode 114′ disposed over the second separation structure 110B and protects a portion of the second OLED material 112′ and the second cathode 114′ within the area 152. The protective photoresist does not cover the second OLED material 112′ and the second cathode 114′ disposed over the first separation structure 110A and the first sub-pixel line 107A.

At operation 714, as shown in FIG. 8O, the second OLED material 112′, the second cathode 114′, and the second assistant cathode 560′ of the second sub-pixel line 107B, disposed over the first sub-pixel line 107A is etched away. The second OLED material 112′, the second cathode 114′, and the second encapsulation layer 116′ disposed over the first sub-pixel line 107A are etched away so that the first assistant cathode 560 of the first sub-pixel line 107A is exposed. The second OLED material 112′, the second cathode 114′, and the second assistant cathode 560′ of the second sub-pixel line 107B is protected by the protective photoresist 416 during the etching process. After the etching process is completed, the protective photoresist 416 is removed and the second OLED material 112′, the second cathode 114′, and the second assistant cathode 560′ that was covered by the protective photoresist during 416 the etching process remains. After the protective photoresist 416 is removed, the first sub-pixel line 107A includes the first OLED material 112, the first cathode 114, and the first assistant cathode 560 of the first sub-pixel line 107A, and the second sub-pixel line 107B includes the second OLED material 112′, the second cathode 114′, and the second assistant cathode 560′ of the second sub-pixel line 107B. The assistant cathode is deposited using ALD and is a conformally deposited on the cathode.

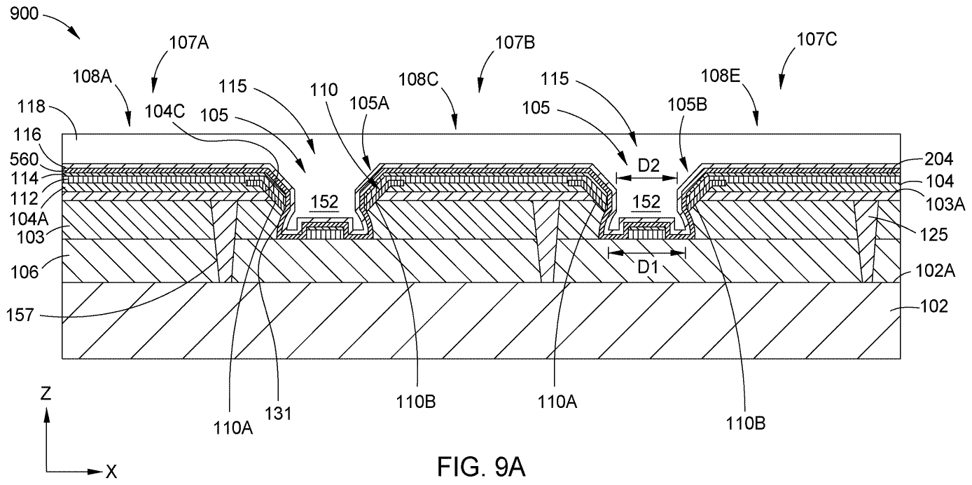

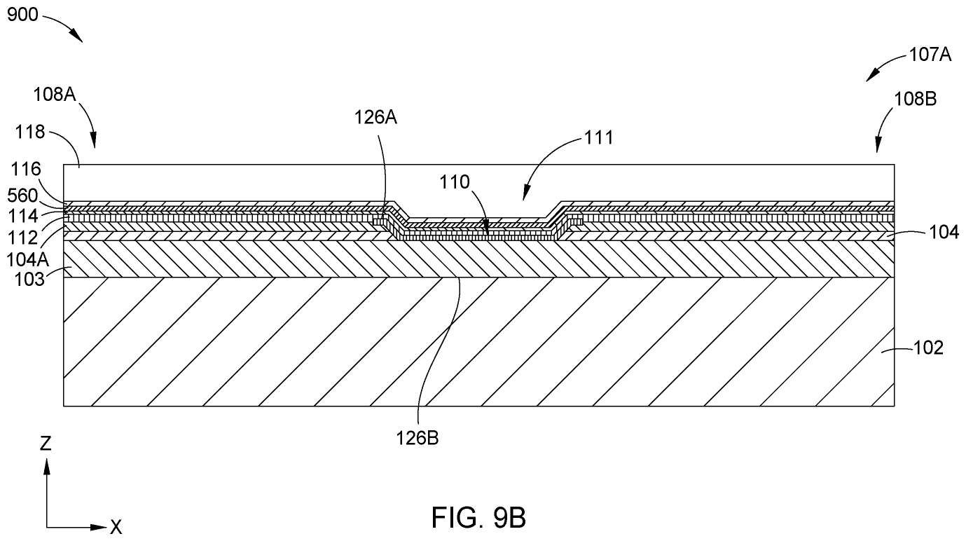

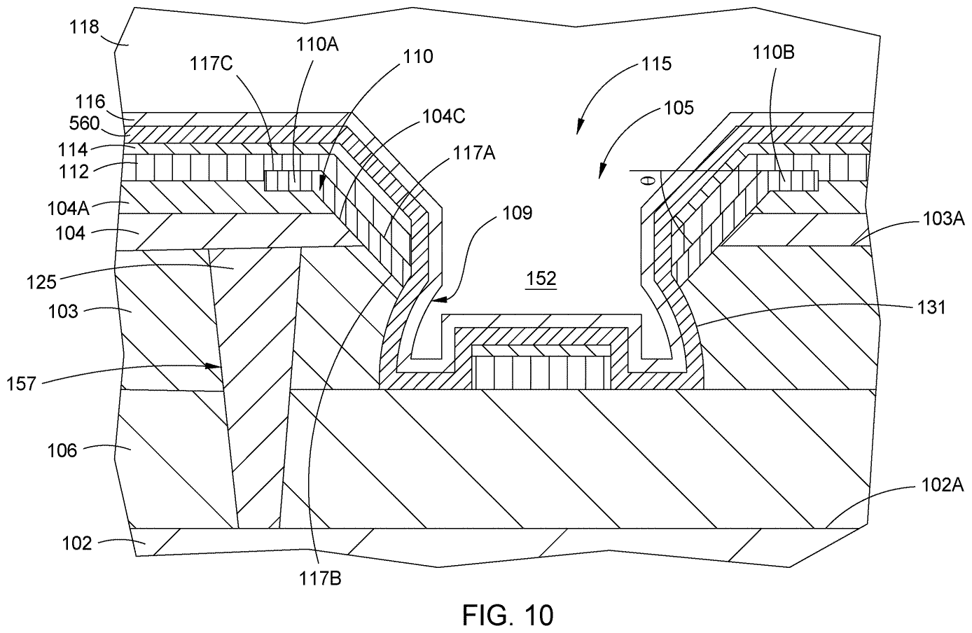

FIG. 9A is a schematic, cross-sectional view of a sub-pixel circuit 900, according to one or more embodiments. The cross-sectional view of FIG. 9A is taken along section line 1B-1B of FIG. 1A (e.g., a pixel plane or x-direction). FIG. 9B is a schematic, cross-sectional view of a sub-pixel circuit 900 according to embodiments. The cross-sectional view of FIG. 9B is taken along section line 1C-1C of FIG. 1A (e.g., a line plane or y-direction). The sub-pixel circuit 900 can be used in place of the sub-pixel circuit 100 or the sub-pixel circuit 500. Identical reference numerals have been used, where possible, to designate identical elements that are common to the figures.

The sub-pixel circuit 900 includes an assistant cathode 560. The assistant cathode 560 is conformally disposed over the cathode 114. In some embodiments, the assistant cathode 560 is conformally disposed on an upper surface of the cathode 114. The assistant cathode is deposited over the cathode 114 using atomic layer deposition. The assistant cathode 560 is made from an assistant cathode material. The assistant cathode material may include a TCO material, such as one or more indium gallium zinc oxide (IGZO) layers, indium zinc oxide (IZO) layers zinc oxide (ZnO), aluminum doped zinc oxide (AZO), indium tin oxide (ITO) or similar material. In one more embodiments, the TCO cathode has a thickness from about 50 nm to about 100 nm. The encapsulation layer 116 is disposed over the assistant cathode 560. The assistant cathode 560 forms a cathode connection and bridges any discontinuities that may exist in the y-direction, as shown in FIG. 9B. Furthermore, the assistant cathode 560 enables the connection of horizontal bus bars outside of the active area. The assistant cathode 560 may bridge the electrical discontinuities in the x-direction, enabling the use of non-line-type sub-pixel arrangements, such as RGB quad type to honeycomb type sub-pixel arrangements. The assistant cathode 560 may act as an encapsulation layer for the OLED material 112. In some embodiments, an encapsulation layer 116 is disposed over the assistant cathode 560.

FIG. 10 is a close up schematic, cross-sectional view of sub-pixel circuit 900. Each separation structure 110 includes a tapered portion 117A, a bottom surface 117B, and an upper portion 117C. The tapered portion 117A extends from the upper portion 117C at an angle θ of about 5° to about 90°, such as about 5° to about 35° compared to a horizontal plane. The bottom surface 117B extends past the sidewall 131 of the isolation structure 103 to form the separation extension 109. The separation extension 109 allows for the separation structure 110 to shadow a portion of the well 105. In one or more embodiments, the bottom surface 117B contacts the outer edge 103B of the isolation structure 103. The bottom surface 117B extends over the outer portion of the anodes 104. The sidewalls 131 and the separation extensions 109 of the adjacent separation structures 110 at least partially define an area 152 within the well 105. The assistant cathode 560 forms a cathode connection and bridges any discontinuities that may exist in the y-direction, e.g., when an angle between the horizontal plane and the tapered portion 117A of the separation structure 110 is too steep (typically)>30°, forming a common cathode that can be connected by horizontal bus bars outside of the active area. In addition, the assistant cathode 560 may bridge the electrical discontinuities in the x-direction, enabling the use of non-line-type sub-pixel arrangements, such as RGB-quad type to honeycomb type sub-pixel arrangements.

Benefits of the present disclosure include increased pixels-per-inch, decreased current leakage, increased device performance, increased device image resolution, decreased cost, and decreased maintenance.

While the foregoing is directed to embodiments of the present disclosure, other and further embodiments of the disclosure may be devised without departing from the basic scope thereof, and the scope thereof is determined by the claims that follow. It is contemplated that one or more aspects disclosed herein may be combined. Moreover, it is contemplated that one or more aspects disclosed herein may include some or all of the aforementioned benefits.

What is claimed is:

1. A sub-pixel circuit, comprising:
at least two isolation structures disposed over a substrate, adjacent isolation structures defining a well;
anodes disposed over an upper surface of the isolation structures, the anodes comprising a tapered surface;
separation structures comprising:
a tapered portion disposed over the tapered surface of the anodes and extending into the well; and
a bottom surface extending past a sidewall of the at least two isolation structures to form a separation extension;
an organic light emitting diode (OLED) material;
a cathode; and
an encapsulation layer.

2. The sub-pixel circuit of claim 1, wherein the isolation structures comprise an isolation material and the separation structures comprise a separation material.

3. The sub-pixel circuit of claim 2, wherein the isolation material is different from the separation material, the isolation material has a first etch rate when exposed to an etchant, the separation material has a second etch rate when exposed to an etchant, and the first etch rate and the second etch rate are different.

4. The sub-pixel circuit of claim 3, wherein the isolation material comprises silicon oxide.

5. The sub-pixel circuit of claim 3, wherein the separation material comprises aluminum oxide.

6. The sub-pixel circuit of claim 1, further comprising a protective layer disposed on the substrate within the well and extending below the isolation structures.

7. The sub-pixel circuit of claim 6, wherein the protective layer comprises aluminum oxide (Al₂O₃), silicon nitride (SiNₓ), silicon oxide (SiO₂), or a combination thereof.

8. The sub-pixel circuit of claim 1, wherein sidewalls of the adjacent isolation structures are separated by a first distance, the well includes an opening having a second distance, and wherein a half of a difference between the first distance and the second distance is about 50 nm to about 200 nm.

9. A device, comprising:
a first sub-pixel and a second sub-pixel each comprising:
isolation structures comprising an isolation material, the isolation structures disposed over a substrate;
anodes disposed over the isolation structures;
a plurality of separation structures, the separation structures disposed over the anodes, the plurality of separation structures further comprising:
an upper portion extending over a portion of an uppermost surface of the anodes;
a lower portion extending past a sidewall of the isolation structures to form an separation extension; and
an intermediate portion spanning between the upper portion and the lower portion;
an organic light emitting diode (OLED) material;
a cathode disposed over the OLED material; and
an assistant cathode disposed over the cathode.

10. The device of claim 9, wherein the assistant cathode comprises a TCO material.

11. The device of claim 10, wherein the TCO material includes one or more indium gallium zinc oxide (IGZO) layers, indium zinc oxide (IZO), layers zinc oxide (ZnO), aluminum doped zinc oxide (AZO), indium tin oxide (ITO).

12. The device of claim 9, wherein an isolation material of the isolation structures has a first etch rate and an separation material of the separation structures has a second etch rate, wherein the first etch rate is different from the second etch rate.

13. The device of claim 9, wherein an encapsulation layer is disposed over the assistant cathode and extends under at least a portion of the separation structures and along a sidewall of the isolation structures.

14. A sub-pixel circuit, comprising:
at least two isolation structures disposed over a substrate, adjacent isolation structures defining a well;
anodes disposed over an upper surface of the isolation structures, the anodes comprising a tapered surface;
separation structures, the separation structures comprising:
a tapered portion disposed over the tapered surface of the anodes; and
a bottom surface extending past a sidewall of the at least two isolation structures to form an separation extension;
an organic light emitting diode (OLED) material;
a cathode disposed over the OLED material;
an assistant cathode disposed over the cathode; and
an encapsulation layer disposed over the assistant cathode.

15. The sub-pixel circuit of claim 14, wherein the assistant cathode comprises a TCO material.

16. The sub-pixel circuit of claim 15, wherein the TCO material includes one or more indium gallium zinc oxide (IGZO) layers, indium zinc oxide (IZO), layers zinc oxide (ZnO), aluminum doped zinc oxide (AZO), indium tin oxide (ITO).

17. The sub-pixel circuit of claim 14, wherein an isolation material of the isolation structures is different from a separation material of an separation structures, the isolation material has a first etch rate when exposed to an etchant, the separation material has a second etch rate when exposed to an etchant, and the first etch rate and the second etch rate are different.

18. The sub-pixel circuit of claim 14, further comprising a protective layer disposed on the substrate within the well and extending below the isolation structures.

19. The sub-pixel circuit of claim 18, wherein the protective layer comprises aluminum oxide (Al₂O₃), silicon nitride (SiNₓ), silicon oxide (SiO₂), or a combination thereof.

20. The sub-pixel circuit of claim 14, wherein a global encapsulation layer fills the well and an opening between the separation structures.
